(19) United States
(12) Patent Application Publication
(10) Pub. No.: US 2007/0184366 A1
(43) Pub. Date: Aug. 9, 2007

(54) DYE CONTAINING CURABLE COMPOSITION, COLOR FILTER, AND PROCESS OF PREPARING COLOR FILTER

(75) Inventor: Hideki TAKAKUWA, Shizuoka-ken (JP)

Correspondence Address: SUGHRUE MION, PLLC, 2100 PENNSYLVANIA AVENUE, N.W., SUITE 800, WASHINGTON, DC, 20037, US

(73) Assignee: FUJIFILM Corporation

(21) Appl. No.: 11/736,852

(22) Filed: Apr. 18, 2007

Related U.S. Application Data
(62) Division of application No. 10/795,988, filed on Mar. 10, 2004.

(30) Foreign Application Priority Data
Mar. 10, 2003 (JP) 2003-62966

(51) Int. Cl. G03F 1/00

(52) U.S. Cl. 430/7

(57) ABSTRACT

The present invention provides a dye-containing curable composition a dye-containing curable composition containing at least an alkali soluble binder, an organic-solvent-soluble dye, a radiation-sensitive compound and a metal complex of a transition element in which the maximum value of a molar absorption coefficient ε in a visible light range is smaller than that of the organic-solvent-soluble dye; a color filter using the curable composition; and a process of preparing the curable composition.

### CROSS-REFERENCE TO RELATED APPLICATION

This application claims priority under 35 USC 119 from Japanese Patent Application No. 2003-62966, the disclosure of which is incorporated by reference herein.

### BACKGROUND OF THE INVENTION

1. Field of the Invention

The present invention relates to a dye-containing curable composition constituting a color filter used for liquid crystal display elements and solid state image pick-up elements and suitable for forming colored images, as well as to a color filter using the dye-containing curable composition and a process of preparing the color filter.

2. Description of the Related Art

As processes for preparing a color filter used for liquid crystal display elements and solid state image pick-up elements, a staining process, a printing process, an electrodeposition process and a pigment dispersion process are known.

In the pigment dispersion process, the color filter is prepared by a photolithographic process using a colored radiation-sensitive composition prepared by dispersing a pigment in a photosensitive composition. The color filter prepared by this process is stable with respect to light, heat and the like since pigments are used. A sufficient degree of positional accuracy can be obtained in this process since the pigment is patterned by the photolithographic process, and this process has been widely used as a process suitable for preparing the color filter for a large screen and high accuracy color display.

In preparing a color filter by the pigment dispersion process, the radiation-sensitive composition is first coated on a substrate with a spin coater or roll coater and dried to form a coating film. Then, colored pixels are obtained by patterned-exposure and development of the coating film. The color filter can be prepared by repeating this operation a number of times corresponding to the number of hues.

A pigment dispersion process using a negative-type photosensitive composition comprising an alkali-soluble resin comprising a photopolymerizable monomer and a photopolymerization initiator together is disclosed in Japanese Patent Application Laid-Open (JP-A) Nos. 1-102469, 2-181704, 2-199403, 4-76062, 5-273411, 6-184482 and 7-140654.

A color filter for a solid state image pick-up element has been required to be finer and more precise in recent years. However, it is difficult to further improve resolution of a color filter according to the conventional pigment dispersion system. This is because the pigment dispersion process is not suitable for applications fine patterning such as a solid state image-pick-up element since color unevenness occurs due to coarse pigment particles.

Art using a dye instead of the pigment has been proposed in consideration of the problems above. However, there arises a problem in that the dye-containing composition is generally inferior to the pigment-containing composition in light fastness.

In order to improve light fastness, Japanese Patent No. 2,986,796 and JP-A No. 11-223720 have proposed a colored glass filter comprising an alcohol-soluble metallic compound such as Ni or Co, and a process of adding a metal complex to a triphenylmethane dye in a resin.

However, all of this art is related to a process that does not required alkali development. Light fastness of the dye tends to be slightly decreased after exposure, alkali development, and subsequent heating processes as compared with a dye that does not undergo such processes. Accordingly, art relating to additives capable of providing light fastness even after the alkali development process has been desired.

A thin film having a thickness of 1.5μ or less is required particularly when the film is used for preparing a color filter for a solid state image pick-up element, unlike in the case of producing a semiconductor. Therefore, a large quantity of dye must be added in the composition for obtaining a sufficient color density. Consequently, it has been a problem that, when patterns are formed by alkali development, development resistance of patterned portions is insufficient and a retained layer rate decreases in a developing step in the case of both negative-type and positive-type photosensitive compositions.

### SUMMARY OF THE INVENTION

It is a first object of the present invention to provide a dye-containing curable composition having high light fastness after alkali development and a good retained layer rate after development.

A second object of the invention is to provide a color filter that uses the dye-containing curable composition, is excellent in hues and resolution, and has high light fastness.

A third object of the invention is to provide a process of preparing a color filter that can suppress decrease of the retained layer rate after alkali development, has good hues and resolution, and is excellent in light fastness, using the dye-containing curable composition.

A first aspect of the invention is to provide a dye-containing curable composition containing at least an alkali soluble binder, an organic-solvent-soluble dye, a radiation-sensitive compound and a metal complex of a transition element in which the maximum value of a molar absorption coefficient ε in a visible light range is smaller than that of the organic-solvent-soluble dye.

A second aspect of the invention is to provide a color filter prepared by using a dye-containing curable composition containing at least an alkali soluble binder, an organic-solvent-soluble dye, a radiation-sensitive compound and a metal complex of a transition element in which the maximum value of a molar absorption coefficient ε in a visible light range is smaller than that of the organic-solvent-soluble.

A third aspect of the invention is to provide a process of preparing a color filter comprising the steps of: applying a dye-containing curable composition containing at least an alkali soluble binder, an organic-solvent-soluble dye, a radiation-sensitive compound and a metal complex of a transition element in which the maximum value of a molar absorption coefficient ε in a visible light range is smaller than that of the organic-solvent-soluble on a substrate; exposing the dye-containing curable composition through a mask, and forming a pattern image by development.

The plurality of steps described above may be repeated a number of times corresponding to the number of desired hues when preparing the color filter having desired hues in the process of preparing the color filter. The step of curing the patterned image by heating and/or exposure is suitably included, if necessary.

### DETAILED DESCRIPTION OF THE INVENTION

The dye-containing curable composition and the color filter constituted using the dye-containing curable composition, and the process of preparing the color filter will be described in detail hereinafter.

Dye-Containing Curable Composition

The dye-containing curable composition of the invention comprises (1) an alkali-soluble binder, (2) an organic-solvent-soluble dye, (3) a radiation-sensitive compound and (4) a metal complex of a transition element in which the maximum value of a molar absorption coefficient ε in a visible light range is smaller than that of the organic-solvent-soluble. The dye-containing curable composition usually contains an organic solvent.

At least one of a photopolymerization initiator and a photo-acid-generating agent may be contained as the (3) radiation-sensitive compound in the dye-containing curable composition constituted of the invention when it is constructed as a negative-type composition. On the other hand, either the photo-acid-generating agent or o-quinone diazide compound may be contained as the (3) radiation-sensitive compound in the dye-containing curable composition structured as a positive-type composition.

The dye-containing composition of the invention may also contain other components such as a monomer and a cross-linking agent. The monomer and photopolymerization initiator may be also contained in the dye-containing composition of the invention structured as the positive-type composition.

(1) Alkali-Soluble Binder

The dye-containing curable composition of the invention comprises at least one alkali-soluble binder. The alkali-soluble binder used in the invention is not particularly restricted so long as it is soluble in an alkali. The alkali-soluble binder is preferably selected from the viewpoint of heat resistance, development ability and availability. The alkali-soluble binder will be described hereinafter.

The alkali-soluble binder is preferably a linear organic polymer, soluble in organic solvents, and is able to be developed with a weak aqueous alkali solution. Such linear organic polymers include polymers having carboxylic acids at the side chains. Examples of the polymer having carboxylic acids at the side chains include methacrylic acid copolymers, acrylic acid copolymers, itaconic acid copolymers, crotonic acid copolymers, maleic acid copolymers and partially esterified maleic acid copolymers as described in JP-A Nos. 59-44615, 59-53836 and 59-71048, and Japanese Patent Application Publication (JP-B) Nos. 54-34327, 58-12577 and 54-25957.

Otherwise, acidic cellulose derivatives having carboxylic acids at the side chains are preferable as the alkali-soluble binder.

Other preferable alkali-soluble binders include adducts of acid anhydrides to polymers having hydroxyl groups, polyhydroxystyrene resins, polysiloxane resins, poly(2-hydroxyethyl(meth)acrylate), polyvinyl pyrrolidone, polyethylene oxide and polyvinyl alcohol.

A Hydrophilic monomer may be copolymerized with the alkali-soluble binder. Examples of such monomer include alkoxyalkyl(meth)acrylate, hydroxyalkyl(meth)acrylate, glycerol (meth)acrylate, (meth)acrylamide, N-methylol acrylamide, secondary or tertiary alkyl acrylamide, dialkylaminoalkyl(meth)acrylate, morpholine (meth)acrylate, N-vinyl pyrrolidone, N-vinyl caprolactam, vinyl imidazole, vinyl triazole, methyl(meth)acrylate, ethyl(meth)acrylate, branched or linear propyl(meth)acrylate, branched or linear butyl(meth)acrylate, and phenoxyhydroxypropyl (meth)acrylate.

Other preferable hydrophilic monomers include those containing tetrahydrofurfulyl group, phosphate, phosphate ester, quaternary ammonium salt, ethyleneoxy chain, propyleneoxy chain, sulfonic acid and salts thereof, and morpholinoethyl groups.

The alkali-soluble binder may have polymerizable groups at the side chain for improving the cross-linking efficiency when the dye-containing composition of the invention is structured as a negative-type composition. Polymers having allyl group, (meth)acrylic or allyloxyalkyl groups at the side chains are also preferable. Examples of the polymer having such polymerizable group will be described below. The polymers having the polymerizable group are not restricted to those shown below, so long as they contain alkali soluble groups such as COOH, OH and ammonium groups, and carbon-carbon unsaturated bonds.

Specific examples of the polymer having the polymerizable group include a compound having an epoxy ring reactive to the OH group and carbon-carbon unsaturated double bonds (for example, glycidyl acrylate) to react with a copolymer of a compound having OH groups (for example 2-hydroxyethyl acrylate), a compound having COOH groups (for example methacrylic acid), and a monomer of an acrylic or a vinyl compound copolymerizable with these compounds.

The compounds having a group reactive to the OH group available include an epoxy ring as well as compounds having acid hydride, isocyanate group or acryloyl groups. A reaction product obtained by allowing a saturated or unsaturated polybasic acid anhydrate to react with a compound obtained by allowing an unsaturated carboxylic acid such as acrylic acid to react with a compound having an epoxy ring as disclosed in JP-A Nos. 6-102669 and 6-1938 may be also used.

Examples of the compound having the alkali soluble group such as COOH group and carbon-carbon unsaturated bond together include Dianal NR series (trade name) manufactured by Mitsubishi Rayon Co., Ltd., Photomer 6173 (trade name; COOH group containing polyurethane acrylic oligomer) manufactured by Diamond Shamrock Co., Ltd., Biscoat R-264 and KS Resist 106 (trade names) manufactured by Osaka Organic Chemical Industry Ltd., Cyclomer-P series and Plakcel CF200 series (trade names) manufactured by Daicel Chemical Industries, Ltd.), and Ebecry 13800 (trade name) manufactured by Daicel UBC Co., Ltd.

For constructing the dye-containing curable composition of the invention as a positive-type composition, the alkali-soluble binder available include phenol-formaldehyde resin, cresol-formaldehyde resin, phenol-cresol-formaldehyde condensation resin, phenol modified xylene resin, copolymers of polyhydroxystyrene, polyhalogenated hydroxystyrene and N-(4-hydroxyphenyl)methacrylamide, and hydroquinone-monomethacrylate copolymers.

Other alkali-soluble binders include sulfonylimide polymers described in JP-A No. 7-28244, and carboxyl group containing polymers described in JP-A No. 7-36184. Various alkali-soluble polymer compounds such as acrylic resins having phenolic hydroxyl groups as described in JP-A No. 51-34711, acrylic resins having sulfonamide groups as described in JP-A No. 2-866, and urethane resins may be also used. These alkali-soluble binders may be used alone, or as a combination of two or more.

A resin in which the alkali soluble group is protected with an acid cleavable group may be used together with the photo-acid-generating agent. This resin is a compound having a —C—O—C— or —C—O—Si— bond, and examples thereof include the following compound (a) to (i):

(a) a compound containing at least one selected from orthocarboxylic acid ester and carboxylic acid amide acetal, which is polymerizable, and having the group as a cross-linking element in the main chain or as a side chain substituent;

(b) an oligomer compound or a polymer compound containing a group selected from repeated acetal groups and ketal groups in the main chain;

(c) a compound containing at least one enol ester group or N-acylaminocarbonate group;

(d) cyclic acetal or ketal of β-ketoester or β-ketoamide;

(e) a compound containing silyether groups;

(f) a compound containing silylenol ether groups;

(g) monoacetal or monoketal having aldehyde or ketone components having a solubility of 0.1 to 100 g/liter in a developer;

(h) ether of tertiary alcohols; and

(i) carboxylate and carbonate of a tertiary allyl or benzyl alcohol.

The acid cleavable compounds in the (a) are described in German Patent Laid-Open (DE-A) Nos. 2,610,842 and 2,928,636. Mixtures containing the compounds in the (b) are described in DE-A Nos. 2,306,248 and 2,718,254. The compounds in the (c) are described in EP Laid-Open (EP-A) Nos. 0,006,626 and 0,006,627. The compounds in the (d) are described in EP-A No. 0,202,196. The compounds in the (e) are described in DE-A Nos. 3,544,165 and 3,601,264. The compounds in the (f) are described in DE-A Nos. 3,730,785 and 3,730,783. The compounds in the (g) are described in DE-A No. 3,730,783. The compounds in the (h) are described in U.S. Pat. No. 4,603,101. The compounds in the (i) are described in U.S. Pat. No. 4,491,628 and the report by M. Frechet et al. (J. Imaging Sci., 30, 59-64, 1986).

The content of these compounds protected with the acid cleavable groups in the dye-containing curable composition is usually 1 to 60% by mass, preferably 5 to 40% by mass, relative to the total solid content.

Polyhydroxystyrene resins, polysiloxane resins, acrylic resins, acrylamide resins and acrylic/acrylamide copolymer resins are preferable among these binders, and acrylic resins, polyhydroxystyrene resins and polysiloxane resins are more preferable from the viewpoint of heat resistance. The acrylic resins, acrylamide resins and acrylic/acrylamide copolymer resins are preferable from the viewpoint of development controlling ability.

The acrylic resins (binders that may contain polymerizable groups) are particularly preferable. Preferable examples of the acrylic resin include copolymers comprising the monomers selected from benzyl(meth)acrylate, (meth)acrylic acid, hydroxyethyl(meth)acrylate and (meth)acrylamide; Cyclomer P series and Prakcel CF200 series (manufactured by Daicel Chemical Industry Co.); Ebecryl 13800 (manufactured by Daicel UBC Co.); Dianal NR series (manufactured by Mitsubishi Rayon Co., Ltd.); and Biscoat R264 and KS Resist 106 (manufactured by Osaka Organic Chemical Industry Ltd.

The alkali-soluble binder is preferably polymers having a weight average molecular weight by of 1000 to 2×10⁵, more preferably polymer having a average molecular weight of 2000 to 1×10⁵, and particularly polymer having a average molecular weight of 5000 to 5×10⁴ measured by GPC and converted into polystyrene.

The content of the alkali-soluble binder in the dye-containing curable composition is preferably 10 to 90% by mass, more preferably 20 to 80% by mass, and particularly 30 to 70% by mass, relative to the total solid content of the composition.

(2) Organic-Solvent-Soluble Dye

The dye-containing curable composition of the invention comprises at least one kind selected from the organic-solvent-soluble dyes (simply named as “dye” hereinafter). The organic-solvent-soluble dyes are not particularly restricted, and color filter dyes known in the are available.

The dyes available include dyes described in JP-A Nos. 64-90403, 64-91102, 1-94301, 6-11614, 5-333207, 6-35183, 6-51115 and 6-194828; Japanese Patent No. 2592207; and U.S. Pat. Nos. 4,808,501, 5,667,920 and 5,059,500. The dyes having chemical structures of triphenylmethane, anthraquinone, benzylidene, oxonol, cyanine, phenothiazine, pyrrolopyrazole azomethin, xanthene, phthalocyanine, benzopyran and indigo dyes may be used. Particularly preferable dyes are pyrazoleazo, anilinoazo, pyrazolotriazoleazo, pyridoneazo and anthrapyridone dyes.

When the composition is formulated as a resist system for developing with water or an alkali, at least one kind selected from acid dyes and derivatives thereof may be suitably used from the viewpoint of completely removing the binder and dye by development. Otherwise, it is preferable to use at least one of the dye appropriately selected from direct dyes, basic dyes, mordant dyes, acid mordant dyes, azoic dyes, disperse dyes, oil soluble dyes and food dyes, and derivatives thereof.

The acid dye and derivatives thereof will be described below. The acid dye is not particularly restricted, so long as it is a dye having acidic groups such as sulfonic acid, carboxylic acid and phenolic hydroxyl groups. However, the acid dye should be soluble in the organic solvent and developer used for preparation and development of the composition, be able to form salts with basic compounds, interact with other component in the curable composition, and have enough light absorbance, light fastness and heat resistance. Therefore, the acid dye is selected by taking all these characteristics into consideration.

While specific examples of the acid dye are described below, the invention is not restricted to these examples. They are the following dyes, and derivatives of these dyes:

acid alizarin violet N;

acid black 1, 2, 24 and 48;

acid blue 1, 7, 9, 15, 18, 23, 25, 27, 29, 40, 42, 45, 51, 62, 70, 74, 80, 83, 86, 87, 90, 92, 96, 103, 108, 112, 113, 120, 129, 138, 147, 150, 158, 171, 182, 192, 210, 242, 243, 249, 256, 259, 267, 278, 280, 285, 290, 296, 315, 324:1, 335 and 340;

acid chrome violet K;

acid fuchsin;

acid green 1, 3, 5, 9, 16, 25, 27, 50, 58, 63, 65, 80, 104, 105, 106 and 109;

acid orange 6, 7, 8, 10, 12, 26, 50, 51, 52, 56, 62, 63, 64, 74, 75, 94, 95, 107, 108, 169 and 173;

acid red 1, 4, 8, 14, 17, 18, 26, 27, 29, 31, 34, 35, 37, 42, 44, 50, 51, 52, 57, 66, 73, 80, 87, 88, 91, 92, 94, 97, 103, 111, 114, 129, 133, 134, 138, 143, 145, 150, 151, 158, 176, 182, 183, 198, 206, 211, 215, 216, 217, 227, 228, 249, 252, 257, 258, 260, 261, 266, 268, 270, 274, 277, 280, 281, 195, 308, 312, 315, 316, 339, 341, 345, 346, 349, 382, 383, 394, 401, 412, 417, 418, 422 and 426;

acid violet 6B, 7, 9, 17 19 and 49;

acid yellow 1, 3, 7, 9, 1, 17, 23, 25, 29, 34, 36, 38, 40, 42, 54, 65, 72, 73, 76, 79, 98, 99, 111, 112, 113, 114, 116, 119, 123, 128, 134, 135, 138, 139, 140, 144, 150, 155, 157, 160, 161, 163, 168, 169, 172, 177, 178, 179, 184, 190, 193, 196, 197, 199, 202, 203, 204, 205, 207, 212, 214, 220, 221, 228, 230, 232, 235, 238, 240, 242, 243 and 251;

direct yellow 2, 33, 34, 35, 38, 39, 43, 47, 50, 54, 58, 68, 69, 70, 71, 86, 93, 94, 95, 98, 102, 108, 109, 129, 136, 138 and 141;

direct orange 34, 39, 41, 46, 50, 52, 56, 57, 61, 64, 65, 68, 70, 96, 97, 106 and 107;

direct red 79, 82, 83, 84, 91, 92, 96, 97, 98, 99, 105, 106, 107, 172, 173, 176, 177, 179, 181, 182, 184, 204, 207, 211, 213, 218, 220, 221, 222, 232, 233, 234, 241, 243, 246 and 250;

direct violet 47, 52, 54, 59, 60, 65, 66, 79, 80, 81, 82, 84, 89, 90, 93, 95, 96, 103 and 104;

direct blue 57, 77, 80, 81, 84, 85, 86, 90, 93, 94, 95, 97, 98, 99, 100, 101, 106, 107, 108, 109, 113, 114, 115, 117, 119, 137, 149, 150, 153, 155, 156, 158, 159, 160, 161, 162, 163, 164, 166, 167, 170, 171, 172, 173, 188, 189, 190, 192, 193, 194, 196, 198, 199, 200, 207, 209, 210, 212, 213, 214, 222, 228, 229, 237, 238, 242, 243, 244, 245, 247, 248, 250, 251, 252, 256, 257, 259, 260, 268, 274, 275 and 293;

direct green 25, 27, 31, 32, 34, 37, 63, 65, 66, 67, 68, 69, 72, 77, 79 and 82;

mordant yellow 5, 8, 10, 16, 20, 26, 30, 31, 33, 42, 43, 45, 56, 50, 61, 62 and 65;

mordant orange 3, 4, 5, 8, 12, 13, 14, 20, 21, 23, 24, 28, 29, 32, 34, 35, 36, 37, 42, 43, 47 and 48;

mordant red 1, 2, 3, 4, 9, 11, 12, 14, 17, 18, 19, 22, 23, 24, 25, 26, 30, 32, 33, 36, 37, 38, 39, 41, 43, 45, 46, 48, 53, 56, 63, 71, 74, 85, 86, 88, 90, 94 and 95;

mordant violet 1, 2, 4, 5, 7, 14, 22, 24, 30, 31, 32, 37, 40, 41, 44, 45, 47, 48, 53 and 58;

mordant blue 1, 2, 3, 7, 8, 9, 12, 13, 15, 16, 19, 20, 21, 23, 24, 26, 30, 31, 32, 39, 40, 41, 43, 44, 48, 49, 53, 61, 74, 77, 83 and 84;

mordant green 1, 3, 4, 5, 10, 15, 19, 26, 29, 33, 34, 35, 41, 43 and 53;

food yellow 3; solvent yellow 14, 82, 94 and 162; solvent orange 2, 7, 11, 15, 26 and 56; solvent blue 25, 35, 37, 38, 55, 59 and 67; solvent red 49.

The following dyes and derivatives of these dyes are preferable among them:

acid black 24;

acid blue 23, 25, 29, 62, 80, 86, 87, 92, 138, 158, 182, 243 and 324:1;

acid orange 8, 51, 56, 74, 63 and 74;

acid red 1, 4, 8, 34, 37, 42, 52, 57, 80, 97, 114, 143, 145, 151, 183, 217 and 249;

acid violet 7;

acid yellow 17, 25, 29, 34, 42, 72, 76, 99, 111, 112, 114, 116, 134, 155, 169, 172, 184, 220, 228, 230, 232 and 243; and

acid green 25.

Azo, xanthene and phthalocyanine acid dyes are also preferable in addition to the dyes above. Examples of these dyes include acid dyes such as C.I. solvent blue 44 and 38, C. I. Solvent orange 45, rhodamine B, rhodamine 110, 2,7-naphthalenedisulfonic acid, 3-[(5-chloro-2-phenoxyphenyl)hydrazono]-3,4-dihydro-4-oxo-5-[(phenylsulfonyl)amino] dye, and derivatives of these dyes.

The acid dyes may be used as derivatives when the acid dye is incorporated into the composition as a constituent so that the dye has a sufficient solubility in the organic solvent used for preparation.

The derivatives of the acid dye available include inorganic salts of the acid dye having acidic groups such as sulfonic acid and carboxylic acid groups, salts of the acid dye with nitrogen containing compounds, and sulfonamides of the acid dye. The derivative is not particularly restricted so long as it is soluble in a solution of the dye-containing curable composition prepared. However, the derivatives of the acid dye should be soluble in the organic solvent and developer used for preparation and development of the composition, and interact with other component in the dye-containing curable composition, and have enough light absorbance, light fastness and heat resistance. Therefore, the acid dye is selected by taking all these characteristics into consideration.

The salt of the acid dye with the nitrogen-containing compound will be described below. Forming a salt between the acid dye and nitrogen-containing compound may be effective for improving solubility (solubility in organic solvents) of the acid dye, heat resistance and light fastness.

The nitrogen containing compound that forms a salt with the acid dye, and the nitrogen containing compound that forms an amide bond with the acid dye to afford a sulfonamide of the acid dye will be described below.

The nitrogen containing compound is selected considering all the characteristics such as solubility of the salt or amide compound in the organic solvent or the developer used for preparation and development, salt forming ability, light absorbance, color value of the dye, interaction between the nitrogen containing compound and other components in the dye-containing curable composition, and heat resistance and light fastness as a coloring agent. The molecular weight of the nitrogen-containing compound is preferably as small as possible when the compound is selected considering only the light absorbance and color value. The molecular weight is preferably 300 or less, more preferably 280 or less, and particularly preferably 250 or less.

While examples of the nitrogen-containing compound are listed below, the invention is not restricted to these examples. The compounds having no —NH— groups are not the nitrogen containing-compound that forms an amide bond in the compounds listed below.

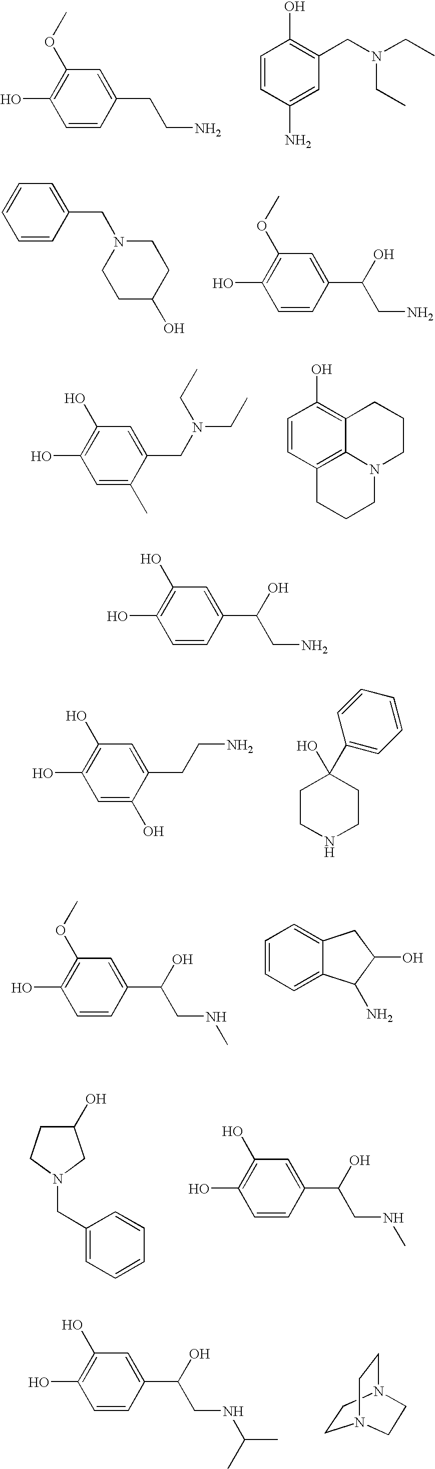

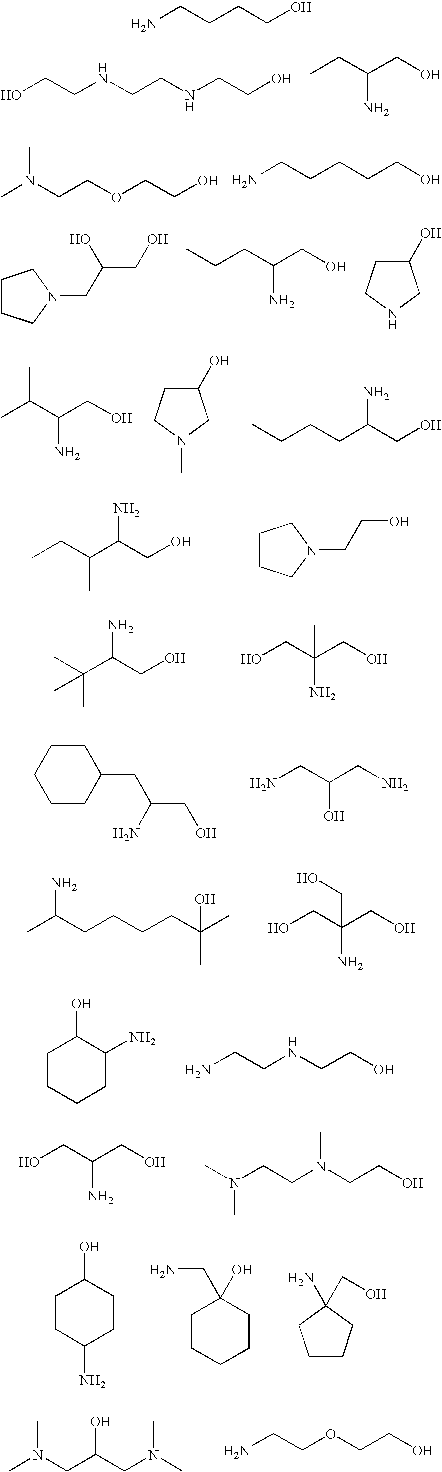

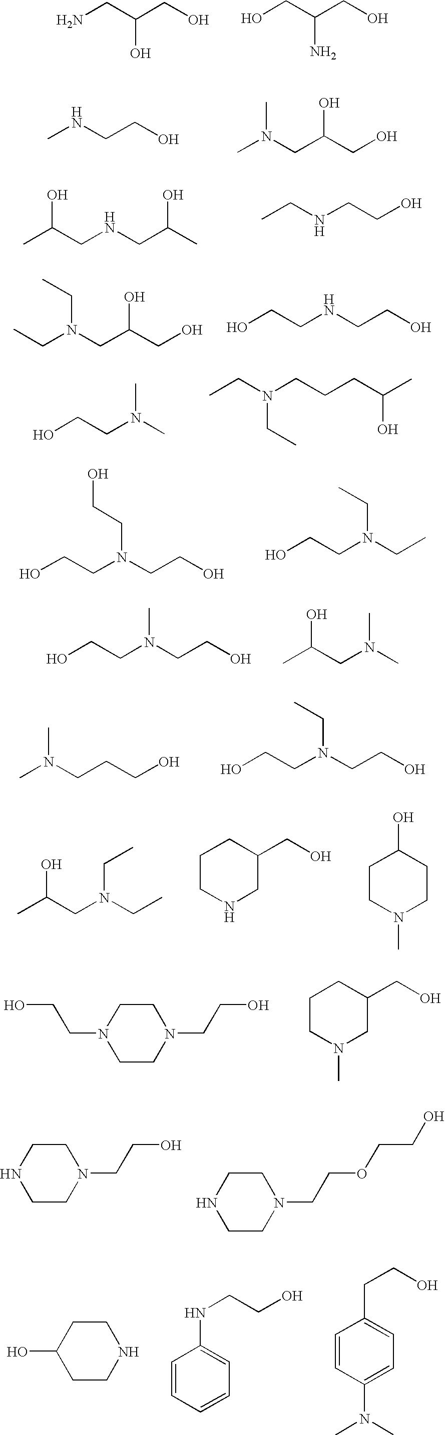

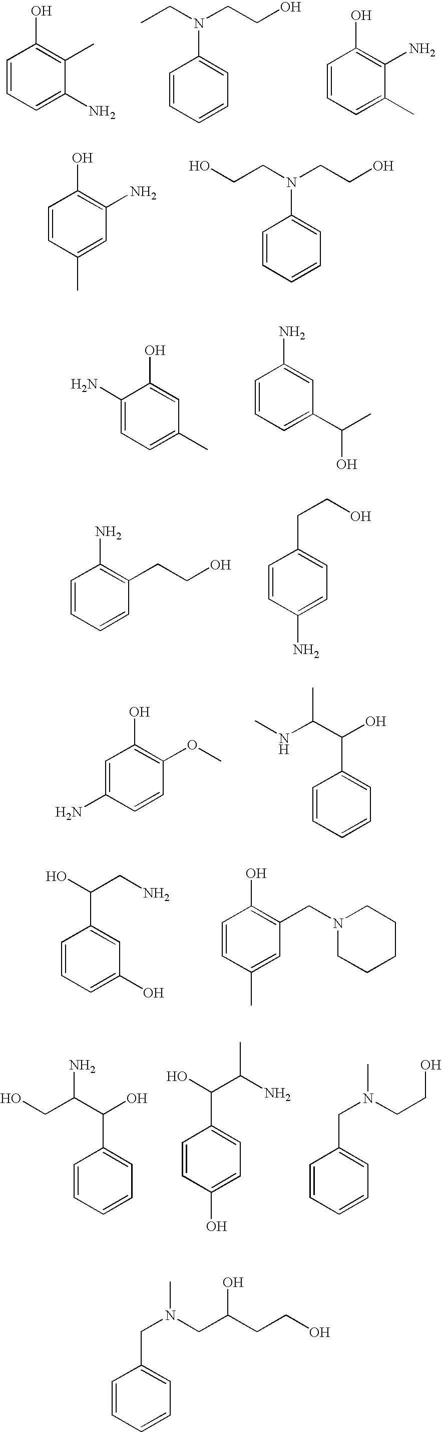

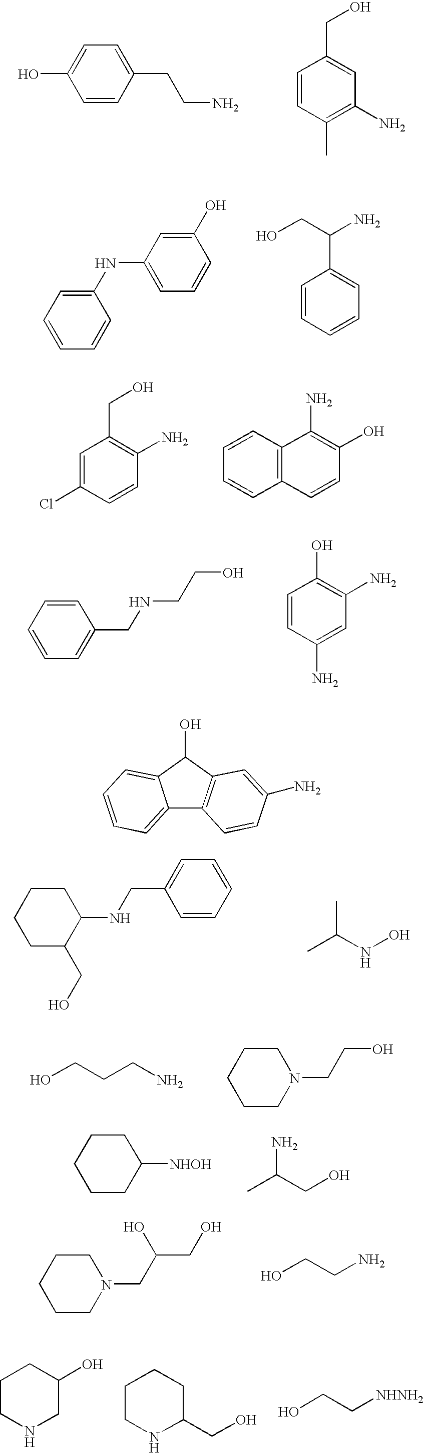

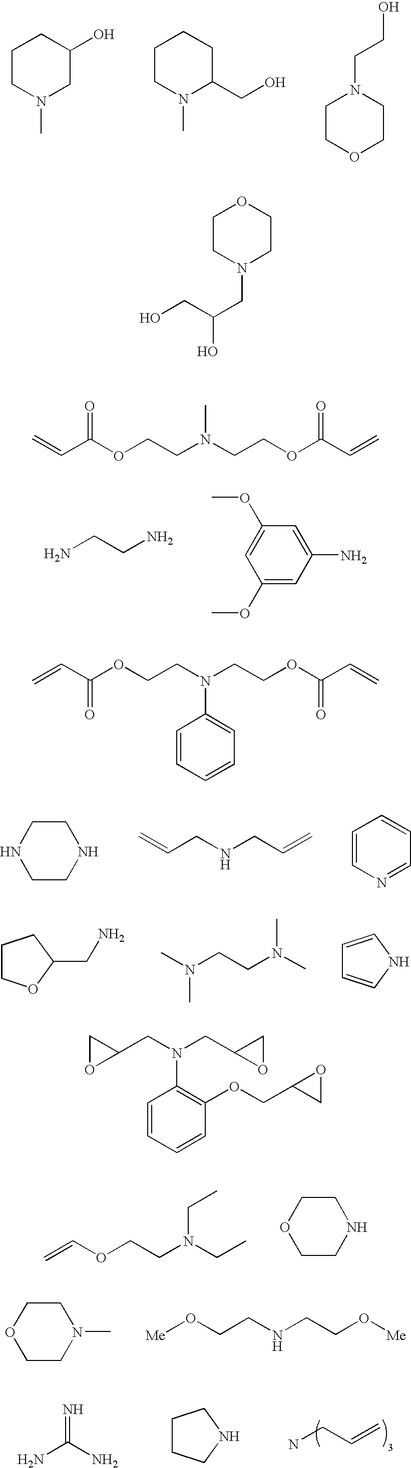

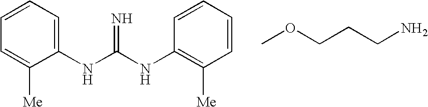

The molar ratio (abbreviated as “n” hereinafter) of the nitrogen-containing compound to the acid dye in the salt between the acid dye and nitrogen containing compound will be described below. The molar ratio n denotes the ratio of the acid dye molecule to an amine compound as a counter ion. The molar ratio n may be freely selected depending on the salt forming condition between the acid dye and amine compound. For example, n is a value satisfying the relation of 0<n≦10 of the number of the functional groups in the acid of the acid dye in most practical cases, and may be selected considering all the required characteristics such as solubility in the organic solvent used and developer, salt forming ability, light absorbance, interaction with other components in the dye-containing curable composition, and light fastness and heat resistance. When n is selected considering only the light absorbance, it satisfies the relation of preferably 0<n≦4.5, more preferably 0<n≦4, and particularly 0<n≦3.5.

The concentration of the organic-solvent-soluble dye will be described below. While the concentration of the organic-solvent-soluble dye in the total solid content in the dye-containing curable composition differs depending on the kind of the dye, it is preferably 0.5 to 80% by mass, more preferably 0.5 to 60% by mass, and particularly preferably 0.5 to 50% by mass.

(3) Radiation-Sensitive Compound

The dye-containing curable composition of the invention comprises at least one kind selected from the radiation-sensitive compounds. The radiation-sensitive compound is able to effect chemical reactions such as generation of radicals, acids and bases by irradiation of radiation such as UV, deep UV, visible light, infrared light and electron beam. The radiation-sensitive compound is used for making the alkali-soluble binder insoluble by cross-linking, polymerization and decomposition of acidic groups, or for making coating layers insoluble to an alkali developer by inducing polymerization of the polymerizable monomer and oligomer remaining in the coating layer or cross-linking of the cross-linking agent.

It is particularly preferable that the dye-containing curable composition of the invention comprises at least any one of the photopolymerization initiator and the photo-acid-generating agent, when the composition is constructed as a negative-type composition. On the other hand, the dye-containing curable composition of the invention preferably contains an o-quinone diazide compound or photo-acid-generating agent when the composition is constructed as a positive-type composition.

The photopolymerization initiator used for constructing the dye-containing curable composition as a negative-type composition.

The photopolymerization initiator is not particularly restricted so long as it is able to polymerize the polymerizable monomer. The photopolymerization initiator is preferably selected from the viewpoint of its properties, polymerization initiation efficiency, absorbing wavelength, availability and cost. The photopolymerization initiator may be added to the positive-type dye-containing curable composition comprising the o-quinone diazide compound, in the case of hardness of the pattern formed is enhance.

Examples of the photopolymerization initiator include at least one active halogen compound selected from halomethyl oxadiazole compounds and halomethyl-s-triazine compounds; 3-aryl substituted coumarin compounds; lophine dimer; benzophenone compounds; acetophenone compounds and derivatives thereof; cyclopentadiene-benzene-iron complex and the salt thereof; and oxime compounds.

Examples of the active halogen compound as the halomethyl oxadiazole compound include 2-halomethyl-5-vinyl-1,3,4-oxadiazole compounds described in JP-B No. 57-6096, 2-trichloromethyl-5-styryl-1,3,4-oxadiazole, 2-trichloromethyl-5-(p-cyanostyryl)-1,3,4-oxadiazole, and 2-trichloromethyl-5-(p-methoxystyryl)-1,3,4-oxadiazole.

Examples of the active halogen compound as the halomethyl-s-triazine compound include vinyl-halomethyl-s-triazine compounds described in JP-B No. 59-1281, 2-(naphto-1-yl)-4,6-bis-halomethyl-s-triazine compounds described in JP-A No. 53-133428, and 4-(p-aminophenyl)-2,6-di-halomethyl-s-triazine compounds.

Other specific examples include 2,4-bis(trichloromethyl)-6-p-methoxystyryl-s-triazine, 2,6-bis(trichloromethyl)-4-(3,4-methylenedioxyphenyl)-1,3,5-triazine, 2,6-bis(trichloromethyl)-4-(4-methoxyphenyl)-1,3,5-triazine, 2,4-bis(trichloromethyl)-6-(1-p-dimethylaminophenyl-1,3-butadienyl)-s-triazine, 2-trichloromethyl-4-amino-6-p-methoxystyryl-s-triazine, 2-(naphtho-1-yl)-4,6-bis-trichloromethyl-s-triazine, 2-(4-methoxy-naphtho-1-yl)-4,6-bis-trichloromethyl-s-triazine, 2-(4-ethoxy-naphtho-1-yl)-4,6-bis-trichloromethyl-s-triazine, 2-(4-butoxy-naphtho-1-yl)-4,6-bis-trichloromethyl-s-triazine, 2-[4-(2-methoxyethyl)-naphtho-1-yl]-4,6-bis-trichloromethyl-s-triazine, 2-[4-(2-ethoxyethyl)-naphtho-1-yl]-4,6-bis-trichloromethyl-s-triazine, 2-[4-(2-butoxyethyl)-naphto-1-yl]-4,6-bis-trichloromethyl-s-triazine, 2-(2-methoxy-naphtho-1-yl)-4,6-bis-trichloromethyl-s-triazine, 2-(6-methoxy-5-methyl-naphtho-2-yl)-4,6-bis-trichloromethyl-s-triazine, 2-(6-methoxy-naphtho-2-yl)-4,6-bis-trichloromethyl-s-triazine, 2-(5-methoxy-naphtho-1-yl)-4,6-bis-trichloromethyl-s-triazine, 2-(4,7-dimethoxy-naphtho-1-yl)-4,6-bis-trichloromethyl-s-triazine, 2-(6-ethoxy-naphtho-2-yl)-4,6-bis-trichloromethyl-s-triazine, 2-(4,5-dimethoxy-naphtho-1-yl)-4,6-bis-trichloromethyl-s-triazine, 4-[p-N,N-di(ethoxycarbonylmethyl)aminophenyl]-2,6-di(trichloromethyl)-s-triazine, 4-[o-methyl-p-N,N-di(ethoxycarbonylmethyl)aminophenyl]2,6-di(trichloromethyl)-s-triazine, 4-[p-N,N-di(chloroethyl)aminophenyl]-2,6-di(trichloromethyl)-s-triazine, 4-[o-methyl-p-N,N-di(chloroethyl)aminophenyl]-2,6-di(trichloroethyl)-s-triazine, 4-(p-N-chloroethylaminophenyl)-2,6-di(trichloromethyl)-s-triazine, 4-(p-N-ethoxycarbonylmethylaminophenol)-2,6-di(trichloromethyl)-s-triazine, 4-[p-N,N-di(phenyl)aminophenyl]-2,6-di(trichloromethyl)-s-triazine, 4-(p-N-chloroethylcarbonylaminophenyl)-2,6-di(trichloromethyl)-s-triazine, 4-[p-N-(p-methoxyphenyl)carmonylaminophenyl]-2,6-di(trichloromethyl)-s-triazine, 4-[m-N,N-di(ethoxycarbonylmethyl)aminophenyl]-2,6-di(trichloromethyl)-s-triazine, 4-[m-bromo-p-N,N-di(ethoxycarbonylmethyl)aminophenyl]-2,6-di(trichloromethyl)-s-triazine, 4-[m-chloro-p-N,N-di(ethoxycarbonylmethyl)aminophenyl]-2,6-di(trichloromethyl)-s-triazine, 4-[m-fluoro-p-N,N-di(ethoxycarbonylmethyl)aminophenyl]-2,6-di(trichloromethyl)-s-triazine, 4-[o-bromo-p-N,N-di(ethoxycarbonylmethyl)aminophenyl]-2,6-di(trichloromethyl)-s-triazine, 4-[o-chloro-p-N,N-di(ethoxycarbonylmethyl)aminophenyl]-2,6-di(trichloromethyl)-s-triazine, 4-[o-fluoro-p-N,N-di(ethoxycarbonylmethyl)aminophenyl]-2,6-di(trichloromethyl)-s-triazine, 4-[o-bromo-p-N,N-di(chloroethyl)aminophenyl]-2,6-di(trichloromethyl)-s-triazine, 4-[o-chloro-p-N,N-di(chloroethyl)aminophenyl]-2,6-di(trichloromethyl)-s-triazine, 4-[o-fluoro-p-N,N-di(chloroethyl)aminophenyl]-2,6-di(trichloromethyl)-s-triazine, 4-[m-bromo-p-N,N-di(chloroethyl)aminophenyl]-2,6-di(trichloromethyl)-s-triazine, 4-[m-chloro-p-N,N-di(chloroethyl)aminophenyl]-2,6-di(trichloromethyl)-s-triazine, 4-[m-fluoro-p-N,N-di(chloroethyl)aminophenyl]-2,6-di(trichloromethyl)-s-triazine, 4-(m-bromo-p-N-ethoxycarbonylmethylaminophenyl)-2,6-di(trichloromethyl)-s-triazine, 4-(m-chloro-p-N-ethoxycarbonylmethyl-aminophenyl)-2,6-di(trichloromethyl)-s-triazine, 4-(m-fluoro-p-N-ethoxycarbonylmethylaminophenyl)-2,6-di(trichloromethyl)-s-triazine, 4-(o-bromo-p-N-ethoxycarbonylmethylaminophenyl)-2,6-di(trichloromethyl)-s-triazine, 4-(o-chloro-p-N-ethoxycarbonylmethylaminophenyl)-2,6-di(trichloromethyl)-s-triazine, 4-(o-fluoro-p-N-ethoxycarbonylmethylaminophenyl)-2,6-di(trichloromethyl)-s-triazine, 4-(m-bromo-p-N-chloroethylaminophenyl)-2,6-di(trichloromethyl)-s-triazine, 4-(m-chloro-p-N-chloroethylaminophenyl)-2,6-di(trichloromethyl)-s-triazine, 4-(m-fluoro-p-N-chloroethylaminophenyl)-2,6-di(trichloromethyl)-s-triazine, 4-(o-bromo-p-N-chloroethylaminophenyl)-2,6-di(trichloromethyl)-s-triazine, 4-(o-chloro-p-N-chloroethylaminophenyl)-2,6-di(trichloromethyl)-s-triazine, and 4-(o-fluoro-p-N-chloroethylaminophenyl)-2,6-di(trichloromethyl)-s-triazine.

Other preferable examples include TAZ-series manufactured by Midori Kagaku Co., Ltd. (for example, trade name: TAZ-107, TAZ-110, TAZ-104, TAZ-109, TAZ-140, TAZ-204, TAZ-113 and TAZ-123), T-series manufactured by PANCHIM Co. (for example, trade name: T-OMS, T-BMP, T-R and T-B), Irgacure series manufactured by Ciba-Geigy Corp. (for example, trade name: Irgacure 651, Irgacure 184, Irgacure 500, Irgacure 1000, Irgacure 149, Irgacure 819 and Irgacure 261), Darocure series (for example, trade name: Darocure 1173), 4,4′-bis(diethylamino)-benzophenone, 2-(o-benzoyloxime)-1-[4-(phenylthio)phenyl]-1,2-octadione, 2-benzyl-2-dimethylamino-4-morphorinobutylophenone, 2,2-dimethoxy-2-phenylacetophenone, 2-(o-chlorophenyl)-4,5-diphenylimidazolyl dimer, 2-(o-fluorophenyl)-4,5-diphenylimidazolyl dimer, 2-(o-methoxyphenyl)-4,5-diphenylimidazolyl dimer, 2-(p-methoxyphenyl)-4,5-diphenylimidazolyl dimer, 2-(p-dimethoxyphenyl)-4,5-diphenylimidazolyl dimer, 2-(2,4-dimethoxyphenyl)-4,5-diphenylimidazolyl dimer, 2-(p-methylmercaptophenyl)-4,5-diphenylimidazolyl dimer, and benzoin isopropylether.

Sensitizers and light stabilizers may be used together with these photopolymerization initiators. Specific examples of them include benzoin, benzoin methylether, 9-fluorenone, 2-chloro-9-fluorenone, 2-methyl-9-fluorenone, 9-anthrone, 2-bromo-9-anthrone, 2-ethyl-9-anthrone, 9,10-anthraquinone, 2-ethyl-9,10-anthraquinone, 2-t-butyl-9,10-anthraquinone, 2,6-dichloro-9,10-anthraquinone, xanthone, 2-methylxanthone, 2-methoxyxanthone, thioxanthone, 2,4-diethylthioxanthone, acrydone, 10-butyl-2-chloroacrydone, benzyl, banzalacetone, p-(dimethylamino)phenylstyrylketone, p-(dimethylamino)phanyl-p-methylstyrrylketone, dibenzophenone, p-(dimethylamino)benzophenone (or Michler's ketone), p-(diethylamino)benzophenone, benzoanthrone, and benzothiazole compounds described in JP-B No. 51-48516, Tinuvin 1130 and Tinuvin 400.

Known Photopolymerization initiators other than those described above may be used together with the dye-containing curable composition of the invention. Examples of them include vicinal polyketolaldonyl compounds described in U.S. Pat. No. 2,367,660, α-carbonyl compounds described in U.S. Pat. Nos. 2,367,661 and 2,367,670, acyloin ether compounds described in U.S. Pat. No. 2,448,828, aromatic acyloin compounds substituted with α-carbohydrates described in U.S. Pat. No. 2,722,512, polynuclear quinone compounds described in U.S. Pat. Nos. 3,046,127 and 2,951,758, combinations of trially imidazole dimer and p-aminophenyl ketone described in U.S. Pat. No. 3,549,367, and benzothiazole compounds/trihalomethyl-s-triazine compounds described in JP-B No. 51-48516.

The content of the photopolymerization initiator in the dye-containing curable composition is preferably 0.01 to 50% by mass, more preferably 1 to 30% by mass, and particularly preferably 1 to 20% by mass relative to the solid content (mass) of the monomer.

A heat polymerization inhibitor is preferably added on addition to the additives above, and preferable examples thereof include hydroquinone, p-methoxyphenol, di-t-butyl-p-cresol, pyrogallol, t-butylcatechol, benzoquinone, 4,4′-thiobis(3-methyl-6-t-butylphenol), 2,2′-methylenebis(4-methyl-6-t-butylphenol) and 2-mercaptobenzimidazole.

The o-Quinone diazide compounds suitable for constructing the dye-containing curable composition into a positive composition will be described below. The o-quinone-diazide compound has at least one o-quinone-diazide group.

Examples of the o-quinone-diazide compound include ester of 1,2-naphthoquinone-2-diazide-5-sulfonylchloride and phenol-formaldehyde resin or cresol-formaldehyde resin; ester of 1,2-naphthoquinone-2-diazide-5-sulfonylchloride and pyrogallol-acetone resin described in U.S. Pat. No. 3,635,709; ester of 1,2-naphthoquinone-2-diazide-5-sulfonylchloride and resorcin-benzaldehyde resin described in JP-B No. 63-13528;

ester of 1,2-naphthoquinone-2-diazide-5-sulfonylchloride and resorcin-pyrogallol-acetone co-condensation resin described in JP-B No. 62-44257; esterified products of polyester having hydroxyl groups at the terminals with 1,2-naphthoquinone-2-diazide-5-sulfonylchloride described in JP-B No. 56-45127; esterified products of homopolymers of N-(4-hydroxyphenyl)methacrylamide or copolymers of the monomer with other copolymerizable monomers with 1,2-naphthoquinone-2-diazide-5-sulfonylchloride described in JP-B No. 50-24641; esters of 1,2-naphthoquinone-2-diazide-5-sulfonylchloride with bisphenol-formaldehyde resins described in JP-B No. 54-29922; esterified products of homopolymers of p-hydroxystyrene or copolymers of the monomer with other copolymerizable monomers with 1,2-naphthoquinone-2-diazide-5-sulfonylchloride described in JP-B No. 52-36043; and esters of 1,2-naphthoquinone-2-diazide-5-sulfonylchloride and polyhydroxybenzophenone.

Examples of known o-quinone-diazide compounds that can be used in the invention include those described in JP-A Nos. 63-80254, 58-5737, 57-111530, 57-111531, 57-114138, 57-142635 and 51-36129, JP-B Nos. 62-3411, 62-51459 and 51-483.

The content of the o-quinone-diazide compound in the dye-containing curable composition is usually 5 to 60% by mass, preferably 10 to 40% by mass, relative to the total solid content (mass) of the composition.

The photo-acid-generating agent will be described below. Known agents may be used as the photo-acid-generating agent.

Examples of the photo-acid-generating agent include diazonium salts described in S. I. Schlesinger, Photogr. Sci. Eng., 18, 387 (1974) and T. S. Bal et al., Polymer, 21, 423 (1980); ammonium salts described in U.S. Pat. Nos. 4,069,055 and 4,069,056 and JP-A No. 3-140140; phosphonium salts described in D. C. Necker et al., Macromolecules, 17, 2468 (1984), C. S. Wen et al., Teh. Proc. Conf. Rad. Curing ASIA, p. 478, Tokyo, October (1988), U.S. Pat. Nos. 4,069,055 and 4,069,056; iodonium salts described in J. V. Crivello et al., Macromolecules, 10(6), 1307 (1977), Chem. & Eng. News, Nov. 28, p. 31(1988), EP No. 104,143, U.S. Pat. Nos. 339,049 and 410,201, and JP-A Nos. 2-150848 and 2-296514; and sulfonium salts described in J. V. Crivello et al., Polymer J., 17, 73 (1985), J. V. Crivello et al., J. Org. Chem., 43, 3055 (1978), W. R. Watt et al, J. Polymer Sci., Polymer Chem. Ed., 22, 1789 (1984), J. V. Crivello et al., Polymer Bull., 14, 279 (1985), J. V. Crivello et al., Macromolecules, 14(5), 1141 (1981), J. V. Crivello et al., J. Polymer Sci. Polymer Chem. Ed., 17, 2877 (1979), EP Nos. 370,693, 233,567, 297,443 and 297,442, U.S. Pat. Nos. 3,902,114, 4,933,377, 410,201, 339,049, 4,760,013, 4,734,444 and 2,833,827, DE Nos. 2,904,626, 3,604,580 and 3,604,581;

selenonium salts described in J. V. Crivello et al., Macromolecules, 10(6), 1307 (1977), J. V. Crivello et al., and J. Polymer Sci., Polymer Chem. Ed., 17, 1047 (1979); onium salts such as arsonium salts described in C. S. Wen et al., Teh. Proc. Conf. Rad. Curing ASIA, p 478, Tokyo, October (1988); organic halogenated compounds described in U.S. Pat. No. 3,905,815, JP-B No. 46-4605, JP-A Nos. 48-36281, 55-32070, 60-239736, 61-169835, 6-169837, 62-58241, 62-212401, 63-70243 and 63-298339; organic metals or organic halides described in K. Meier et, al., J. Rad. Curing, 13(4), 26 (1986), T. P. Gill et al., Inorg. Chem., 19, 3007 (1980), D. Astruc, ACC. Chem. Res., 19(12), 377 (1896), and JP-A No. 2-161445;

photo-acid-generating agents having o-nitrobenzyl protective groups described in S. Hayase et al., J. Polymer Sci., 25, 753 (1987), E. Reichmanis et al., J. Polymer Sci., Polymer Chem. Ed., 23, 1 (1985), Q. Q. Zhu et al., J. Photochem., 36, 85, 39, 317 (1987), B. Amit et al., Tetrahedron Lett., (24), 2205 (1973), D. H. R. Barton et al., J. Chem. Soc., 3571 (1965), P. M. Collins et al., J. Chem. Soc., Perkin I, 1695 (1975), M. Rudinstein et al., Tetrahedron Lett., 17, 1445 (1975), J. W. Walker et al., J. Am. Chem. Soc., 110, 7170 (1988), S. C. Busman et al., J. Imaging Technol., 11(4), 191 (1985), H. M. Houlihan et al., Macromolecules, 21, 2001 (1988), P. M. Collins et al, J. Chem. Soc., Chem. Commun., 532 (1972), S. Hayase et al., Macromolecules, 18, 1799 (1985), E. Reichmanis et al., J. Electrochem. Soc., Solid State Sci. Technol., 130(6), F. M. Houlihan et al., Macromolecules, 21, 2001 (1988), EP Nos. 0,290,750, 046,083, 156,535, 271,851 and 0,388,343, U.S. Pat. Nos. 3,901,710 and 4,181,531, and JP-A Nos. 60-198538 and 53-133022; and

compounds that generate sulfonic acid by photodecomposition represented by iminosulfnate described in M. Tunooka et al., Polymer Preprints Japan, 35(8), G. Berner et al., J. Rad. Curing, 13(4), W. J. Mijs et al., Coating technol., 55(697), 45(1983), Akzo, H. Adachi et al., Polymer Preprints, Japan, 37(3), EP Nos. 0,199,672, 84,515, 199,672, 044,115 and 0,101,122, U.S. Pat. Nos. 4,618,564, 4,371,605 and 4,431,774, and JP-A Nos. 64-18143, 2-245756 and 4-365048; and disulfone compounds described in JP-A No. 61-166544.

The content of the photo-acid-generating agent that generates an acid by decomposition by irradiate of an active light or a radiation in the dye-containing curable composition is usually 0.001 to 40% by mass, preferably 0.01 to 20% by mass, and more preferably 0.1 to 5% by mass relative to the total mass of the composition.

(4) Metal Complex of a Transition Element

The dye-containing curable composition of the invention comprises at least one kind selected from metal complex of a transition element in which the maximum value of a molar absorption coefficient ε in a visible light range is smaller than that of the organic-solvent-soluble dye. Negative-type, neutral or positive monofunctional ligands or polyfunctional ligands are coordinated around a transition metal atom or transition metal ion at the center in the metal complex of a transition element. Using the metal complex of a transition element permits light fastness of the dye-containing curable composition and of the color filter constructed by using the composition to be effectively improved. Moreover, using the metal complex of a transition element permits retained layer rate after development of the dye-containing curable composition to be effectively improved.

In the present invention, the maximum value of a molar absorption coefficient ε in a visible light range (380 to 780 nm) of the metal complex of a transition element is smaller than that of the organic-solvent-soluble dye.

The metal complex of a transition element preferably has the maximum value of a molar absorption coefficient ε in the visible light range of 0 to 8,000 from the viewpoint of clearness of the color. More preferably the metal complex of a transition element has the maximum value of a molar absorption coefficient ε of 0 to 6,000, most preferably 0 to 3,000.

Examples of the transition metal atoms in the metal complex of a transition elements, and transition metals constituting the transition metal ions include scandium (Sc), titanium (Ti), vanadium (V), chromium (Cr), manganese (Mn), iron (Fe), cobalt (Co), nickel (Ni), copper (Cu), yttrium (Y), zirconium (Zr), niobium (Nb), molybdenum (Mo), technetium (Tc), ruthenium (Ru), rhodium (Rh), palladium (Pd), silver (Ag), lanthanum (La), cerium (Ce), praseodymium (Pr), neodymium (Nd), promethium (Pm), samarium (Sm), europium (Eu), gadolinium (Gd), terbium (Tb) dysprosium (Dy), holmium (Ho), erbium (Er), thulium (Tm), ytterbium (Yb), lutetium (Lu), hafnium (Hf), tantalum (Ta), tungsten (W), rhenium (Re), osmium (Os), iridium (Ir), platinum (Pt) and gold (Au).

Preferable examples of the metal complex of a transition element include those constructed by transition metals belonging to the first series (or fourth period), for example, those constructed by scandium (Sc), titanium (Ti), vanadium (V), chromium (Cr), manganese (Mn), iron (Fe), cobalt (Co), nickel (Ni) and copper (Cu).

More preferable examples of the metal complex of a transition elements include those constructed by the transition metals belonging to the fourth period and forming divalent transition metal ions, or those constructed by Ti²⁺, V²⁺, Cr²⁺, Mn²⁺, Fe²⁺, Co²⁺, Ni²⁺ and Cu²⁺.

Especially preferable examples of the metal complex of a transition elements include those constructed by Co²⁺, or Ni²⁺. The most preferable examples of the metal complex of a transition elements include those constructed by Co²⁺.

The metal complex of a transition element is preferably obtained by coordinating a ligand in which the maximum value of a molar absorption coefficient ε in the visible light range is 0 to 3000 by the single ligand, on a transition metal. The ligand has the maximum value of a molar absorption coefficient ε in a visible light range of more preferably 0 to 2000 by the single ligand, further preferably 0 to 1000.

A molecular weight of one ligand in the metal complex of a transition element is preferably 20 or more and less than 300.

Commonly used ligands may be used for the ligand in the metal complex of a transition element, and either monodentate ligands, for example, bidentate ligands may be suitably used.

Specific example of the above-mentioned ligand includes fluoro, chloro, bromo, iodo, hydroxo, aqua, tetrahydrofuran, ethylene glycol dimethyl ether, acetonitrile, benzonitrile, oxo, peroxyo, carbonyl, carbonate, oxalato, acetato, ethanolato, 1-butanethiolato, thiophenolato, 2,2′-thiobis(4-t-octyl)phenolate, acetylacetonato, 2,2,6,6-tetramethyl-3,5-heptadionato, trifluoroacetylacetonato, hexafluoroacetylacetonato, ethylacetoacetonato, thiocyanato, isothiocyanato, diethyldithiocarbamate, di-n-butyldithiocarbamate, cyano, amine, dimethylamine, diethylamine, tetraethylammonium, piperidine, N-methylaniline, pyridine, 2-phenylpyridine, ethylenediamine, N,N,N′,N′-tetramethylethylenediamine, 1,2-diaminocyclohexane, 2,2′-pyridine, 1,10-phenanthroline, ethylenediamine tetraacetate, 1,4,8,11-tetraazacyclotetradecane, tris(2-aminoethyl)amine, sulfato, nitro, nitrite, phosphato, diisopropyldithiophosphate, diethyldithiophosphate, triethylphosphine, tributylphosphine, tricyclohexylphosphine, dimethylphenylphosphine, triphenylphosphine, diphenylphosphine, tricyclohexylphosphine, cyclopentadiene, pentamethylcyclopentadiene, cyclooctene, 1,5-cyclooctadiene, bicyclo[2,2,1]hepta-2,5-diene, benzene, naphthalene, aryl and the like.

As preferable ligands among the above-mentioned ligands, ligands not containing an aromatic ring therein are mentioned. Specific examples include fluoro, chloro, bromo, iodo, hydroxo, aqua, tetrahydrofuran, ethylene glycol dimethyl ether, acetonitrile, oxo, peroxyo, carbonyl, carbonato, oxalato, acetato, ethanolato, 1-butanethiolato, acetylacetonato, 2,2,6,6-tetramethyl-3,5-heptadionato, trifluoroacetylacetonato, hexafluoroacetylacetonato, ethylacetoacetonato, thiocyanato, isothiocyanato, diethyldithiocarbamate, diethyldithiocarbamate, cyano, amine, dimethylamine, diethylamine, tetraethylammonium, ethylenediamine, N,N,N′,N′-tetramethylethylenediamine, 1,2-diaminocyclohexane, ethylenediamine tetraacetato, 1,4,8,11-tetraazacyclotetradecane, tris(2-aminoethyl)amine, sulfato, nitro, nitrito, phosphato, diisopropyldithiophosphate, diethyldithiophosphate, triethylphosphine, tributylphosphine, tricyclohexylphosphine, cyclooctene, 1,5-cyclooctadiene, bicyclo[2,2,1]hepta-2,5-diene, aryl and the like. As the ligand, Acetato, acetylacetonato, hexafluoroacetylacetonato, thiocyanato, diethyldithiocarbamate and diethyldithiocarbamate are preferable.

The content of the metal complex of a transition element in the dye-containing curable composition is preferably 40% by mass or less, more preferably 30% by mass or less, further preferably 20% by mass or less, and most preferably 0.5 to 15% by mass with respect to the organic-solvent-soluble dye.

While specific examples of the metal complex of a transition element are listed below, the invention is not restricted to these examples.

Examples of the metal complex of a transition element include α-methylferrocene methanol, titanium(III) chloride tetrahydrofuran complexes, titanium(IV) chloride tetrahydrofuran complex, zirconium(IV) chloride tetrahydrofuran complex, hafnium chloride tetrahydrofuran complex, vanadium(III) chloride tetrahydrofuran complex, 1-butanethiol copper(I) salt, tetra(dimethylamino)titanium, tetra(diethylamino)titanium, thiophenol copper(I) salt, μ-dichlorotetraethylene dirhodium, potassium trichloro(ethylene)platinate(II) monohydrate, allylpalladium chloride dimer, chloro(1,5-hexadiene)rhodium(I) dimer, chlorobis(cyclooctene)rhodium(I) dimer, chlorobis(cyclooctene)iridium(I) dimer, (1,5-cyclooctadiene)dimethylplatinum(II), dichloro(1,5-cyclooctadiene)ruthenium(I) polymer, dicyclo(1,5-cyclooctadiene)palladium(II), dichloro(1,5-cyclooctadiene)platinum(II), dibromo(1,5-cyclooctadiene)platinum(II), (1,5-cyclooctadiene)diiodoplatinum(II), bis(1,5-cyclooctadiene)rhodium(I) tetrafluoroboron, bis(1,5-cyclooctadiene)nickel(0), chloro(1,5-cyclooctadiene)rhodium(I) dimer, chloro(1,5-cyclooctadiene)iridium(I) dimer, (bicyclo[2.2.1]hepta-2,5-diene)dichlororuthenium(II) polymer, bis(bicyclo[2.2.1]hepta-2,5-diene)rhodium(I) perchlorate, (bicyclo[2.2.1]hepta-2,5-diene)chlororhodium(I) dimer, (bicyclo[2.2.1]hepta-2,5-diene)dichloropalladium(II), titanium(III) chloride ethyleneglycol dimethylether complex, niobium(III) chloride ethyleneglycol dimethylether complex, niobium(III) bromide ethyleneglycol dimethylether complex, nickel (II) bromide ethyleneglycol dimethylether complex, niobium(IV) chloride tetrahydrofuran complex, chromium(III) chloride tetrahydrofuran complex, copper(I) bromide dimethylsulfide complex, cis-bis(diethylsulfide)platinum(II) chloride, (dimethylsulfide)gold(I) chloride, tris(ethylenediamine)cobalt(III) chloride dihydrate, tris(ethylenediamine)rhodium(III) chloride trihydrate, dichloro(ethylenediamine)palladium(II), dichloro(ethylenediamine)platinum(II), dichlorobis(ethylenediamine)palladium(II), dichloro(N,N,N′,N′-tetramethylethylenediamine)palladium (II), bis(cis-1,2-diaminocyclohexane)nickel(II) chloride, (1,2-diaminocyclohexane)platinum(II) chloride, titanium(IV)(triethanolaminate)isopropoxide, bis(tetraethylammonium)tetrabromocopper(II), bis(tetraethylammonium)tetrabromomanganese(II), bis(tetraethylammonium)tetrabromocobalt (II) tetraphenylphosphonium acetate dichlorodioxoruthenium(Iv), Copper (II) acetylacetonate, lanthanum acetylacetonate hydrate, cerium(III) acetylacetonate hydrate, europium(III) acetylacetonate hydrate, gadolinium (III) acetylacetonate hydrate, yttrium acetylacetonate hydrate, titanium(IV) oxide acetylacetonate, zirconium(IV) acetylacetonate, vanadium(III) acetylacetonate, vanadyl acetylacetonate, chromium(III) acetylacetonate, bis(acetylacetonate) molybdenum (IV) dioxide, manganese(II) acetylacetonate, manganese(III) acetylacetonate, iron(III) acetylacetonate, cobalt(II) acetylacetonate, cobalt(III) acetylacetonate, nickel(II) acetylacetonate, ruthenium(III) acetylacetonate, rhodium(III) acetylacetonate, palladium(II) acetylacetonate, iridium(III) acetylacetonate, platinum(II) acetylacetonate, (1,5-cyclooctadiene)(2,4-pentadionato) rhodium(I), (bicyclo[2.2.1]hepta-2,5-diene)(2,4-pentadionato) rhodium(I), titanium diisopropoxybis(2,4-pentanedionato), copper bis(2,2,6,6-tetramethyl-3,5-heptanedionato), yttrium tris(2,2,6,6-tetramethyl-3,5-heptanedionato), neodymium tris(2,2,6,6-tetramethyl-3,5-heptanedionato), erbium tris(2,2,6,6-tetramethyl-3,5-heptanedionato), samarium tris(2,2,6,6-tetramethyl-3,5-heptanedionato), thulium tris(2,2,6,6-tetramethyl-3,5-heptanedionato), nickel(II) bis(2,2,6,6-tetramethyl-3,5-heptanedionato), lanthanum tris(2,2,6,6-tetramethyl-3,5-heptanedionato), praseodymium tris(2,2,6,6-tetramethyl-3,5-heptanedionato), europium tris(2,2,6,6-tetramethyl-3,5-heptanedionato), gadolinium tris(2,2,6,6-tetramethyl-3,5-heptanedionato), dysprosium tris(2,2,6,6-tetramethyl-3,5-heptanedionato), holmium tris(2,2,6,6-tetramethyl-3,5-heptanedionato), ytterbium tris(2,2,6,6-tetramethyl-3,5-heptanedionato), thallium(I) trifluoroacetylacetonate, copper(II) trifluoroacetylacetonate, zirconium (IV) trifluoroacetylacetonate, thallium(I) hexafluoroacetylacetonate, copper(II) hexafluoroacetylacetonate hydrate, yttrium hexafluoroacetylacetonate dihydrate, manganese(II) hexafluoroacetylacetonate trihydrate, cobalt(II) hexafluoroacetylacetonate hydrate, nickel (II) hexafluoroacetylacetonate hydrate, palladium(II) hexafluoroacetylacetonate, (acetylacetonate)(1,5-cyclooctadiene)iridium(I), praseodymium tris[3-(trifluoro-methylhydroxymethylene)-(+)-camphorate], europium tris[3-(trifluoro-methylhydroxymethylene)-(+)-camphorate], erbium tris[3-(trifluoro-methylhydroxymethylene)-(+)-camphorate], ytterbium tris[3-(trifluoro-methylhydroxymethylene)-(+)-camphorate], bis[3-(heptafluoropropylhydroxymethylene)-(+)-camphorate]oxo vanadium, praseodymium tris[3-(heptafluoropropylhydroxymethylene)-(+)-camphorate], preseodymium tris[3-heptafluoropropylhydroxymethylene]-(−)-camphorate, europium tris[3-heptafluoropropylhydroxymethylene]-(+)-camphorate, europium tris[3-heptafluoropropylhydroxymethylene]-(−)-camphorate, erbium tris[3-heptafluoropropylhydroxymethylene]-(+)-camphorate, erbium tris[3-heptafluoropropylhydroxymethylene]-(−)-camphorate, ytterbium tris[3-heptafluoropropylhydroxymethylene]-(+)-camphorate, ytterbium tris[3-heptafluoropropylhydroxymethylene]-(−)-camphorate, diamine(1,1-cyclobutanedicarboxylate) platinum(II), titanium(IV) bis(ammonium lactate)dihydroxide, titanium(IV) bis(ethylacetoacetate)diiopropoxide, [1,2,3,4-tetrakis(methoxycarbonyl)-1,3-butadiene-1,4-diyl]platinum, bis(acetnitrile)dichloro palladium(II), bis(acetnitrile)chloronitro palladium(II), bis(acetonitrile) molybdenum(IV) chloride, tetrakis(acetonitrile) palladium(II) tetrafluoroborate, cis-bis(acetnitrile)dichloro platinum(II), tetrekis(acetnitrile) copper(I) heafluorophosphate, tetraethylammonium bis(acetnitrile)tetrachloro ruthenium(III), bis(diethyldithiocarbamate)dioxo molybdenum(VI), dichlorobis(triethylphosphine) palladium(II), cis-dichlorobis(triethylphosphine) platinum(II), trans-dichlorobis(triethylphosphine) platinum(II), dichlorobis(tributylphosphine) nickel(II), dibromobis(tributylphosphine) nickel(II), oxalate bis(triethylphosphine) platinum(II) hydrate, dichlorobis(tricyclohexylphosphine) palladium(II), iodo(trimethylphosphite) copper(I), iodo(triethylphosphite) copper(I), chloro(pyridine)bis(deimehtylglyoximate) cobalt(III), benzene ruthenium(II) chloride dimer, dichloro(p-cimene) ruthenium(II) dimer, (+)-di-μ-chlorobis{2-[1-(dimethylamino)]ethyl}phenyl-C,N-dipalladium, di-μ-chlorobis{2-[1-(diethylamino)]ethyl}phenyl-C,N-dipalladium, di-μ-chlorobis{2-(dimethylamino)]methyl}phenyl-C,N-dipalladium, bis(salicylaldehyde) cobalt(II) dihydrate, tris(dibenzylideneacetone) dipalladium(0), tris(dibenzoylmethanate) iron(III), bis(benzonitrile)dichloro palladium(II), cis-bis(benzonitrile)dichloro platinum(II), trichlorotris(dimethylphenylphosphine) rhenium(III), [tris(dimethylphenylphosphine)](2,5-norbornadiene) rhodium(I) hexafluorophosphate, tetrakis(methyldiphenylphosphine) palladium(0), (1,5-cyclooctadiene)bis(methyldiphenylphosphine) iridium(I) hexafluorophosphate, tris(triphenylphosphine) copper(I) chloride, bis(triphenylphosphine) copper(I) nitrate, chloro(triphenylphosphine) gold(I), trichlorooxobis(triphenylphosphine) rhenium(V), iododioxobis(triphenylphosphine) rhenium(V), dichlorobis(triphenylphosphine) cobalt(II), chlorotris(triphenylphosphine) cobalt(I), tetrakis(triphenylphosphine) nickel(0), dichlorobis(triphenylphosphine) nickel(II), dibromobis(triphenylphosphine) nickel(II), dichlorotris(triphenylphosphine) ruthenium(II), dichlorotetrakis(triphenylphosphine) ruthenium(II), trans-dibromobis(triphenylphosphine) palladium(II), chlorotris(triphenylphosphine) rhodium(I), bromotris(triphenylphosphine) rhodium(I), nitrosyltris(triphenylphosphine) rhodium(I), dichlorobis(triphenylphosphine) palladium(II), tetrakis(triphenylphosphine) palladium(0), tetrakis(triphenylphosphine) platinum(0), cis-dichlorobis(triphenylphosphine) platinum(II), trans-dichlorobis(triphenylphosphine) platinum(II), dioxobis(triphenylphosphine) platinum(IV), ethylenebis(triphenylphosphine) platinum(0), (bicyclo[2.2.1]hepta-2,5-diene)[bis(triphenylphosphine)]rhodium(I) hexafluorophosphate, bis(acetate)bis(triphenylphosphine) palladium(II), trans-benzyl(chloro)bis(triphenylphosphine) palladium(II), dichlorobis[methylenebis(diphenylphosphine)]dipalladium, [1,2-bis(triphenylphosphino)ethane]iron(II) chloride, [1,2-bis(diphenylphosphino)ethane]cobalt(II) chloride, [1,2-bis(diphenylphosphino)ethane]nickel (II) chloride, [1,2-bis(diphenylphosphino)ethane]palladium(II) chloride, bis[1,2-bis(diphenylphosphino)ethane]palladium(0), [1,1,1-tris(diphenylphosphinomethyl)ethane]rhodium(I) chloride, (N-3-allyl)[(2S,3S)-(+)-bis(diphenylphosphino)butane]palladium(II) perchlorate, (bicyclo[2.2.1]hepta-2,5-diene)[(2S,3S)-(+)-bis(diphenylphosphino)butane]rhodium(I) perchlorate, [1,3-bis(diphenylphosphino)propane]dichloro nickel(II), [(R)-(+)-2,2′-bis(diphenylphosphino)1,1′-binaphthyl]chloro(p-cumene) ruthenium chloride, [(S)-(−)-2,2′-bis(diphenylphosphino)1,1′-binaphthyl]chloro(p-cumene) ruthenium chloride, bis[(R)-(−)-2,2′-bis(diphenylphosphino)1,1′-binaphtyl]rhodium (I) perchlorate, [(R)-(+)-2,2′-bis(diphenylphosphino)1,1′-binaphthyl](1,5-cyclooctadiene) rhodium(I) perchlorate, [(S)-(−)-2,2′-bis(diphenylphosphino)1,1′-binaphthyl](1,5-cyclooctadiene) rhodium(I) perchlorate, [(R)-(+)-2,2′-bis(diphenylphosphino) 1,1′-binaphthyl]palladium(II) chloride, tetrakis(triphenylphosphite) nickel(0), tris[N-(diphenylphosphinyl)-p,p-diphenylphosphinic amidate-O,O′]praseodymium, bis(1,5-cyclooctadiene)bis(1H-pyrazolate) diiridium, tetrakis(pyridine)cobalt(II) bis(chromate), cis-dichlorobis(pyridine) platinum (II), (1,5-cyclooctadiene)(Pyridine)(tricyclohexylphosphine) iridium(I) hexafluorophosphate, trichlorobis(2-phenylpyridine) rhodium(III) dimer, tris(2,2′-bipyridine) iron(II) hexafluorophosphate, cis-bis(2,2′-bipyridine)dichloro ruthenium(II) hydrate, tris(2,2′-bipyridyl) ruthenium(II) chloride hexahydrate, (2,2′-bipyridine)dichloro palladium(II), (2,2′-bipyridine)dichloro platinum(II), dichloro(2,2′,6′,2″-terpyridine) platinum(II) dihydrate, dichloro(1,10-phenanthroline) copper(II), dibromo(1,10-phenanthroline) copper(II), dinitrate(1,10-phenanthroline) copper(II), tris(1,10-phenanthroline) iron(II) hexafluorophosphate, tris(1,10-phenanthroline) iron(III) hexafluorophosphate, tris(1,10-phenanthroline) ruthenium(II) chloride hydrate, dichloro(1,10-phenanthroline) palladium(II), dichloro(1,10-phenanthroline) platinum(II), N,N′-bis(salicylidene)ethylenediamino-cobalt(II), N,N′-bis(salicylidene)ethylenediamino nickel(II), bis(salicylideneiminate-3-propyl)methylamino cobalt(II), (R,R)-(−)-N,N′-bis(3,5-di-t-butylsalicylidene)-1,2-cyclohexanediamino manganese(III) chloride, (S,S)-(+)-N,N′-bis(3,5-di-t-butylsalicylidene)-1,2-cyclohexanediamino manganese (III) chloride, N,N′-bis(salicylidene)dianilino cobalt(II), N,N′-bis(salicylidene)-1,2-phenylenediamino cobalt(II) hydrate, tris(cyclopentadienyl) scandium, bis(cyclopentadienyl) vanadium, bis(cyclopentadienyl) chromium, ferrocene, ferrocenium hexafluorophosphate, ferrocenium hexafluoroborate, bis(cyclopentadienyl) cobalt, bis(cyclopentadienyl)nickel, bis(cyclopentadienyl) ruthenium, cyclopentadienyl titanium trichloride, bis(cyclopentadienyl) titanium dichloride, bis(cyclopentadienyl) titanium pentasulfide, bis(cyclopentadienyl) titanium bis(trifluoromethanesulfonate), bis(cyclopentadienyl) zirconium dichloride, bis(cyclopentadienyl) zirconium bis(trifluoromethane sulfonate), bis(cyclopentadienyl) hafnium dichloride, bis(cyclopentadienyl) vanadium dichloride, bis(cyclopentadienyl) niobium dichloride, bis(cyclopentadienyl) molybdenum dichloride, bis(pentamethylcyclopentadienyl) manganese, 1,1′-dimethylferrocene, bis(pentamethylcyclopentadienyl) iron, 1,2-deferrocene ethane, butylferrocene, vinylferrocene, bis(2,4-cyclopentadiene-1-yl)[(4-methylbicyclo[2.2.1]heptane)-2,3-diyl]methylene]titanium, ferrocene methanol, 1,1′-ferrocenedimethanol, (dimethylaminomethyl)ferrocene, (R)-(+)-N,N-dimethy-1-ferrocenylethylamine, (S)-(−)-N,N,dimethyl-1-ferrocenylethylamine, ferrocene carboxyaldehyde, acetylferrocene, 1,1′-diacetylferrocene, ferrocene carboxylic acid, 1,1′-ferrocene dicarboxylic acid, dimethyl-1,1′-ferrocene dicarboxylate, 1,1″-[(4,4′-bipyperidine)-1,1′-diyldicarbonyl]bis[1′-(methoxycarbonylferrocene)], ferrocene acetonitrile, benzoylferrocene, 1,1′-bis(diphenylphosphino) ferrocene, (−)-(R)-1-[(S)-2-(diphenylphosphino)ferrocenyl]ethymethyl ether, (+)-(S)-1-[(R)-2-(diphenylphosphino)ferrocenyl]ethylmethylether, [1,1′-bis(diphenylphosphino)ferrocene]dichloropalladium(II), (−)-(R)—N,N-dimethyl-1-[(S)-2-(diphenylphosphino)ferrocenyl]ethylamine, (+)-(S)—N,N-dimethyl-1-[(S)-2-(diphenylphosphino)ferrocenyl]ethylamine, dichloro[(R)—N,N-dimethyl-1-[(S)-2-(diphenylphosphino)ferrocenyl]ethylamine]palladium, dichloro[(S)—N,N-dimethyl-1-[(R)-2-(diphenylphosphino)ferrocenyl]ethylamine]palladium, (−)-(R)—N,N,-dimethyl-1-[(S)-1′,2-bis(diphenylphosphino)ferrocenyl]ethylamine, (+)-(S)—N,N-dimethyl-1-[(R)-1′,2-bis(diphenylphosphino)ferrocenyl]ethylamine, trans-4-[2-(1-ferrocenyl)-vinyl]-1-methylpyridinium iodide, chlorocyclopentanedienylbis(triphenylphosphine) ruthenium(II), (bicyclo[2.2.1]hepta-2,5-diene)[1,1′-bis(diphenylphosphino)ferrocene]ruthenium(I) perchlorate, bis(pentamethylcyclopentadienyl) zirconium dichloride, pentamethylcyclopentadienyl ruthenium(III) chloride polymer, pentamethylcyclopentadienyl rhodium chloride dimer, pentamethylcyclopentadienyl iridium(III) chloride dimer, cyclohexadienyl iron(0) tricarbonyltetrafluoroborate, cycloheptatriene chromium tricarbonyl, cycloheptatriene molybdenum tricarbonyl, cyclooctatetraene iron tricarbonyl, bicyclo[2.2.1]hepta-2,5-diene molybdenum tetracerbonyl, tricarbonyl(4-methoxy-1-methylcyclohexadene) iron tetrafluoroborate, tricarbonyl(2-methoxycyclohexadiene) iron tetrafluoroborate, tetramethylammonium(1-hydroxyethylidene)pentacarbonyl chromium, cis-tetracerbonylbis(pyperidine) molybdenum, (acetylacetonate)dicarbonyl rhodium(I), (acetylacetonate)dicarbonyl illidium(I), cyclopentadienyl molybdenum tricarbonyl dimer, cyclopentadienyl tungsten tricarbonyl dimer, cyclopentadienyl manganese tricarbonyl, cyclopentadienyl rhenium tricarbonyl, cyclopentadienyl iron dicarbonyl iodide, cyclopentadienyl iron dicarbonyl dimer, cyclopentadienyl cobalt dicarbonyl, cyclopentadienyl nickel carbonyl dimer, methylcyclopentadienyl molybdenum tricarbonyl dimer, (methylcyclopentadienyl)-manganese tricarbonyl, dicarbonylcyclopentadienyl(dimehtylsulfoniumethylide) iron tetrafluoroborate, benzene chromium tricarbonyl, mesitylene chromium tricarbonyl, mesitylene tungsten tricarbonyl, 1,2,3,4-tetrahydronaphthalene chromium tricarbonyl, naphthalene chromium tricarbonyl, anisole chromium tricarbonyl, N-methylaniline chromium tricarbonyl, o-toluidine chromium tricarbonyl, (methylbenzoate) chromium tricarbonyl, di-n-butylthiocarbamate nickel(II), n-butylamino[2,2′-thiobis(4-t-octyl)phenolate]nickel(II), n-butylamino[2,2′-thiobis(4-t-octyl)phenolate]cobalt(II), bis[2,2′-thiobis(4-t-octyl)phenolate]nickel(II), [2,2′-thiobis(4-t-octyl)phenolate]nickel(II) hydrate, [2,2′-thiobis(4-t-octyl)phenolate]nickel(II) ethylamine, bis(butyl-3,5-di-t-butyl-4-hydroxobenzylphosphonate) nickel(II), nickel chloride hexahydrate, cobalt chloride hexahydrate, manganese chloride tetrahydrate, di-n-butyldithiocarbamate cobalt(II), di-n-butyldithiocarbamate copper(II), diisopropyldithiophosphate nickel(II), diethyldithiophosphate palladium, diethyldithiophosphate platinum, tetrakispyridine iron(II) chloride, tetrakispyridine iron(II) bromide, tetrakisisoquinoline iron(II) chloride, tetrakisisoquinoline iron(II) bromide, tetrakisisoquinoline iron(II) iodide, tetrakispyridine iron(II) isocyanate, tetrakisβ-picoline iron(II) bromide, and tetrakis-γ-picoline iron(II) bromide.

The preferable metal complex of a transition element comprises fourth period transition metals.

Specific examples of the preferable metal complex of a transition element include α-methylferrocene methanol, titanium(III) chloride tetrahydrofuran complex, titanium(IV) chloride tetrahydrofuran complex, vanadium(III) chloride tetrahydrofuran complex, 1-butanethiol copper(I) salt, tetra(dimethylamino) titanium, tetra(diethylamino) titanium, thiophenol copper(I) salt, bis(1,5-cyclooctadiene) nickel(0), titanium(III) chloride ethyleneglycol dimethylether complex, nickel(II) bromide ethyleneglycol dimethylether complex, chromium(III) chloride tetrahydrofuran complex, Copper(I) bromide dimethylsulfide complex, tris(ethylenediamine) cobalt(II) chloride dihydrate, bis(cis-1,2-diaminocyclohexane) nickel(II) chloride, titanium(IV) (triethanolaminato)isopropoxide, bis(tetraethylammonium)tetrabromo copper(II), bis(tetraethylammonium)tetrabromo manganese(II), bis(tetraethylammonium)tetrabromo manganese(II), Copper(II) acetylacetonate, titanium(IV) oxide acetylacetonate, vanadium(III) acetylacetonate, vanadylacetylacetonate, chromium(III) acetylacetonate, manganese (II) acetylacetonate, manganese (III) acetylacetonate, iron(III) acetylacetonate, cobalt(II) acetylacetonate, cobalt(III) acetylacetonate, nickel(II) acetylacetonate, titanium diisopropoxidebis(2,4-pentandionato), copper bis(2,2,6,6-tetramethyl-3,5-heptanedionato), nickel(II) bis(2,2,6,6-tetramethyl-3,5-heptanedionato), copper(II) trifluoroacetylacetonate, copper(II) hexafluoroacetylacetonate hydride, manganese(II) hexafluoroacetylacetonate trihydrate, cobalt(II) hexafluoroacetylacetonate hydrate, nickel (II) hexafluoroacetylacetonate hydrate, bis[3-(heptafluoropropylhydroxymethylene)-(+)-camphorate]oxovanadium, titanium(IV) bis(ammoniumlactate)dihydroxide, titanium(IV) bis(ethylacetoacetate)diisopropoxide, tetrakis(acetonitrile)copper(I) hexafluorophosphate, dichlorobis(tributylphosphine) nickel(II), dibromobis(tributylphosphine) nickel(II), iodo(trimethylphosphite) copper(I), iodo(triethylphosphite) copper(I), chloro(pyridine)bis(dimethylglyoximate) cobalt(III), bis(salicylaldehyde)cobalt(II) dihydrate, tris(benzoylmethanate) iron(III), tris(triphenylphosphine) copper(I) chloride, bis(triphenylphosphine) copper(I) nitrate, dichlorobis(triphenylphosphine) cobalt(II), chlorotris(triphenylphosphine) cobalt(I), tetrakis(triphenylphosphine) nickel(0), dichlorobis(triphenylphosphine)nickel(II), dibromobis(triphenylphosphine) nickel(II), [1,2-bis(triphenylphosphino)ethane]iron(II) chloride, [1,2-bis(diphenylphosphino)ethane]cobalt(II) chloride, [1,2-bis(diphenylphosphino)ethane]nickel(II) chloride, tetrakis(pyridine)cobalt(II) bis(chromate), tris(2,2′-bipyridine)iron(II) hexafluorophosphate, dichloro(1,10-phenanthroline) copper(II), dibromo(1,10-phenanthroline) copper(II), dinitrate (1,10-phenanthroline)copper(II), tris(1,10-phenanthroline) iron(II) hexafluorophosphate, tris(1,10-phenanthroline) iron(III) hexafluorophosphate, N,N′-bis(salicylidene)ethylenediamine cobalt(II), N,N′-bis(salicylidene)ethylenediamine nickel(II), bis(salicylideneininate-3-propyl)methylamino cobalt(II), (R,R)-(−)-N,N′-bis(3,5-di-t-butylsalicylidene)-1,2-cyclohexanediamino manganese(III) chloride, (S,S)-(+)-N,N′-bis(3,5-di-t-butylsalicylidene)-1,2-cyclohexanediamino manganese(III) chloride, N,N′-bis(salicylidene)dianilino cobalt(II), N,N′-bis(salicylidene)-1,2-phenylenediamino cobalt(III) monohydrate, tris(cyclopentadienyl)scandium, bis(cyclopentadienyl) vanadium, bis(cyclopentadienyl) chromium, ferrocene, ferrocenium hexafluorophosphate, ferrocenium hexafluoroborate, bis(cyclopentadienyl)cobalt, bis(cyclopentadienyl) nickel, cyclopentadienyl titanium trichloride, bis(cyclopentadienyl)titanium dichloride, bis(cyclopentadienyl) titanium pentasulfide, bis(cyclopentadienyl) titanium bis(trifluoromethanesulfonate), bis(cyclopentadienyl) vanadium dichloride, bis(pentamethylcyclopentadienyl) manganese, 1,1′-dimethylferrocene, bis(pentamethylcyclopentadienyl) iron, 1,2-deiferrocene ethane, butylferrocene, vinylferrocene, bis(2,4-cyclopentadiene-1-yl)[(4-methylbicyclo[2.2.1]heptane-2,3-diyl)methylene]titanium, ferrocene methanol, 1,1′-ferrocene dimethanol, (dimethylaminomethyl)ferrocene, (R)-(+)-N,N-dimethyl-1-ferrocenyl ethylamine, (S)-(−)-N,N-dimethyl-1-ferrocenyl ethylamine, ferrocene carboxyaldehyde, acetylferrocene, 1,1′-diacetylferrocene, ferrocene carboxylic acid, acetylferrocene, 1,1′-ferrocene dicarboxylic acid, dimethyl-1,1′-ferrocene dicarboxylate, 1,1″-[(4,4′-bipyperidine)-1,1′-diyldicarbonyl]bis[1′-(methoxycarbonyl)ferrocene], ferrocene acetonitrile, benzoylferrocene, 1,1′-bis(diphenylphosphino)ferrocene, (−)-(R)-1-[(S)-2-(diphenylphosphino)ferrocenyl]ethylmethylether, (+)-(S)-1-[(R)-2-(diphenylphosphino)ferrocenyl]ethylmethylether, (−)-(R)—N,N-dimethyl-1-[(S)-2-(diphenylphosphino)ferrocenyl]ethylamine, (+)-(S)—N,N-dimethyl-1-[(S)-2-(diphenylphosphino)ferrocenyl]ethylamine, (−)-(R)—N,N-dimethyl-1-[(S)-1′,2-bis(diphenylphosphino)ferrocenyl]ethylamine, (+)-(S)—N,N-dimethyl-1-[(R)-1′,2-bis(diphenylphosphino)ferrocenyl]ethylamine, trans-4-[2-(1-ferrocenyl)vinyl]-1-methylpyridinium iodide, cyclohexadienyl iron(0) tricarbonyltetrafluoroborate, cyclohaptatriene chromium tricarbonyl, cyclooctatetraene iron tricarbonyl, tricarbonyl(4-methoxy-1-methylhexadiene) iron tetrafluoroborate, tricarbonyl(2-methoxycyclohexadiene) iron tetrafluoroborate, tetramethylammonium(1-hydroxyethylidene)pentacarbonyl chromium, cyclopentadienyl manganese tricarbonyl, cyclopentadienyl iron dicarbonyl iodide, cyclopentadienyl iron dicarbonyl dimer, cyclopentadienyl cobalt dicarbonyl, cyclopentadienyl nickel carbonyl dimer, (methylcyclopentadienyl)-manganese tricarbonyl, dicarbonyl cyclopentadienyl(dimethylsulfoniumethylide) iron tetrafluoroborate, benxene chromium tricarbonyl, mesitylene chromium tricarbonyl, 1,2,3,4-tetrahydronaphthalene chromium tricarbonyl, naphthalene chromium tricarbonyl, anisol chromium tricarbonyl, N-methylaniline chromium tricarbonyl, o-toluidine chromium tricarbonyl, (methylbenzoate) chromium tricarbonyl, di-n-butyldithiocarbamate nickel(II), n-butylamino[2,2′-thiobis(4-t-octyl)phenolate]nickel(II), n-butylamino[2,2′-thiobis(4-t-octyl)phenolate]cobalt(II), bis[2,2′-thiobis(4-t-octyl)phenolate]nickel(II), [2,2′-thiobis(4-t-octyl)phenolate]nickel(II) hydrate, [2,2′-thiobis(4-t-octyl)phenolate]nickel(II) ethylamine, bis(butyl-3,5-di-t-butyl-4-hydroxobenzylphosphate) nickel(II), nickel chloride hexahydrate, cobalt chloride hexahydrate, manganese chloride tetrahydrate, di-n-butyldithiocarbamate cobalt(II), di-n-butyldithiocarbamate copper(II), diiospropyldithiophosphate nickel(II), tetrakispyridine iron(II) chloride, tetrakispyridine iron(II) bromide, tetrakisisoquinoline iron(II) chloride, tetrakisisoquinoline iron(II) bromide, tetrakisisoquinoline iron(II) iodide, tetrakispyridine iron(II) isocyanate, tetrakis-β-picoline iron(II) bromide, and tetrakis-γ-picoline iron(II) bromide.

Divalent transition metal ions are more preferable. Specific examples of the divalent transition metal include α-methylferrocene methanol, nickel(II) bromide ethyleneglycol dimethylether complex, bis(cis-1,2-diaminocyclohexane) nickel (II) chloride, bis(tetraethylammonium)tetrabromo copper(II), bis(tetraethylammonium)tetrabromo manganese(II), bis(tetraethylammonium)tetrabromo cobalt(II), copper(II) acetylacetonate, manganese(II) acetylacetonate, cobalt(II) acetylacetonate, nickel (II) acetylacetonate, copper bis(2,2,6,6-tetramethyl-3,5-heptanedionato), nickel(II) bis(2,2,6,6-tetramethyl-3,5-heptanedionato), copper(II) trifluoroacetylactonate, copper(II) hexafluoroacetylactonate hydrate, manganese (II) hexafluoroacetylactonate trihydrate, cobalt(II) hexafluoroacetylactonate hydrate, nickel (II) hexafluoroacetylactonate hydrate, dichlorobis(tributylphosphine) nickel(II), dibromobis(tributylphosphine) nickel(II), bis(salicylaldehyde) cobalt(II) dihydrate, dichlorobis(triphenylphosphine) cobalt(II), dichlorobis(triphenylphosphine) nickel(II), dibromobis(triphenylphosphine) nickel(II), [1,2-bis(triphenylphosphino)ethane]iron(II) chloride, [1,2-bis(triphenylphosphino)ethane]cobalt(II) chloride, [1,2-bis(diphenylphosphino)ethane]nickel(II) chloride, tetrakis(pyridine) cobalt(II) bis(chromate), tris(2,2′-bipyridine)iron(II) hexafluorophosphate, dichloro(1,10-phenanthrolone) copper(II), dibromo(1,10-phenanthrolone) copper(II), dinitrate(1,10-phenanthrolone) copper(II), tris(1,10-phenanthrolone) iron (II) hexafluorophosphate, N,N′-bis(salicylidene)ethylenediamino cobalt(II), N,N′-bis(salicylidene)ethylenediamino nickel(II), bis(salicylideneiminate-3-propyl)methylamino cobalt(II), N,N′-bis(salicylidene)dianilino cobalt(II), N,N′-bis(salicylidene)-1,2-phenylenediamino cobalt(II) monohydrate, bis(cyclopentadienyl) vanadium, bis(cyclopentadienyl) chromium, ferrocene, bis(cyclopentadienyl) cobalt, bis(cyclopentadienyl)nickel, bis(pentamethylcyclopentadienyl) manganese, 1,1′-dimethylferrocene, bis(pentamethylcyclopentadienyl) iron, 1,2-deiferrocene ethane, butylferrocene, vinylferrocene, ferrocene methanol, 1,1-ferrocene dimethanol, (dimethylaminomethyl) ferrocene, (R)-(+)-N,N-dimethyl-1-ferrocenyl ethylamine, (S)-(−)-N,N-dimethyl-1-ferrocenyl ethylamine, ferrocene carboxyaldehyde, acetylferrocene, 1,1′-diacetylferrocene, ferrocene carboxylic acid, acetylferrocene, 1,1′-ferrocene dicarboxylic acid, dimethyl-1,1′-ferrocene dicarboxylate, 1,1″-[4,4′-bipiperidine]-1,1′-diyl dicarbonyl]bis[1′-(methoxycarbonyl)ferrocene], ferrocene acetonitrile, benzoylferrocene, 1,1′-bis(diphenylphosphino)ferrocene, (−)-(R)-1-[(S)-2-(diphenylphosphino)ferrocenyl]ethylmethyl ether, (+)-(S)-1-[(R)-2-(diphenylphosphino)ferrocenyl]ethylmethyl ether, (−)-(R)—N,N-dimethyl-1-[(S)-2-(diphenylphosphino)ferrocenyl]ethylamine, (+)-(S)—N,N-dimethyl-1-[(S)-2-(diphenylphosphino)ferrocenyl]ethylamine, (−)-(R)—N,N-dimethyl-1-[(S)-1′,2-bis(diphenylphosphino)ferrocenyl]ethylamine, (+)-(S)—N,N-dimethyl-1-[(R)-1′,2-bis(diphenylphosphino)ferrocenyl]ethylamine, trans-4-[2-(1-ferrocenyl)-vinyl]-1-methylpyridinium iodide, cyclopentadienyl iron carbonyl iodide, cyclopentadienyl iron dicarbonyl dimer, di-n-butyldithiocarbamate nickel(II), n-butylamino[2,2′-thiobis(4-t-octyl)phanolate]nickel(II), n-butylamino[2,2′-thiobis(4-t-octyl)phanolate]cobalt(II), bis[2,2′-thiobis(4-t-octyl)phanolate]nickel(II), [2,2′-thiobis(4-t-octyl)phanolate]nickel(II) hydrate, [2,2′-thiobis(4-t-octyl)phanolate]nickel(II) ethylamine, bis(butyl-3,5-di-t-butyl-4-hydroxybenzylphosphonate)nickel(II), nickel chloride hexahydrate, cobalt chloride hexahydrate, manganese chloride tetrahydrate, di-n-butyldithiocarbamate cobalt(II), di-n-butyldithiocarbamate copper(II), diiopropyl dithiophosphate nickel(II), tetrakispyridine iron(II) chloride, tetrakispyridine iron(II) bromide, tetrakisisoquinoline iron (II) chloride, tetrakisisoquinoline iron (II) bromide, tetrakisisoquinoline iron (II) iodide, tetrakispyridine iron (II) isocyanate, tetrakisβ-picoline iron(II) bromide, and tetrakisγ-picoline iron(II) bromide.

The metal complex of a transition element in which the transition metal is Co²⁺ and Ni²⁺ is more preferable. Specific examples include nickel(II)bromide ethylene glycol dimethyl ether complex, bis(cis-1,2-diaminocyclohexane)nickel(II)chloride, bis(tetraethylammonium)tetrabromocobalt(II), cobalt(II)acetylacetonate, nickel(II)acetylacetonate, nickel(II)bis(2,2,6,6-tetramethyl-3,5-heptadionate), cobalt(II)hexafluoroacetylacetonate hydrate, nickel(II)hexafluoroacetylacetonate hydrate, dichlorobis(tributylphosphine)nickel(II), dibromobis(tributylphosphine)nickel(II), bis(salicylaldehyde)cobalt(II)dihydrate, dichlorobis(triphenylphosphine)cobalt(II), dichlorobis(triphenylphosphine)nickel(II), dibromobis(triphenylphosphine)nickel(II), [1,2-bis(diphenylphosphino)ethane]cobalt(II)chloride, [1,2-bis(diphenylphosphino)ethane]nickel(II)chloride, tetrakis(pyridine)cobalt(II)bis(chromate), N,N′-bis(salicylidene)ethylenediaminocobalt(II), N,N′-bis(salicylidene)ethylenediaminonickel(II), bis(salicylideneiminate-3-propyl)methylaminocobalt(II), N,N′-bis(salicylidene)dianilinocobalt(II), N,N′-bis(salicylidene)-1,2-phenylenediaminocobalt(II)hydrate, bis(cyclopentadienyl)cobalt, bis(cyclopentadienyl)nickel, di-n-butyldithiocarbamatenickel(II), n-butylamino[2,2′-thiobis(4-t-octyl)phenolate]nickel(II), n-butylamino[2,2′-thiobis(4-t-octyl)phenolate]cobalt(II), bis[2,2′-thiobis(4-t-octyl)phenolate]nickel(II), [2,2′-thiobis(4-t-octyl)phenolate]nickel(II)hydrate, [2,2′-thiobis(4-t-octyl)phenolate]nickel(II)ethylamine, bis(butyl-3,5-di-t-butyl-4-hydroxobenzylcarbonate)nickel(II), nickel chloride hexahydrate, cobalt chloride hexahydrate, di-n-butyldithiocarbamatecobalt(II), diisopropyldithiophosphatenickel(II) and the like.

Ligands not containing an aromatic ring therein are more preferably mentioned. Specific examples include nickel(II)bromide ethylene glycol dimethyl ether complex, bis(cis-1,2-diaminocyclohexane)nickel(II)chloride, bis(tetraethylammonium)tetrabromocobalt(II), cobalt(II)acetylacetonate, nickel(II)acetylacetonate, nickel(II) bis(2,2,6,6-tetramethyl-3,5-heptadionate), cobalt(II)hexafluoroacetylacetonate hydrate, nickel (II) hexafluoroacetylacetonate hydrate, dichlorobis(tributylphosphine)nickel(II), dibromobis(tributylphosphine)nickel(II), di-n-butyldithiocarbamatenickel(II), nickel chloride hexahydrate, cobalt chloride hexahydrate, di-n-butyldithiocarbamatecobalt(II), and diisopropyldithiophosphatenickel(II).

Among these, the particularly preferable metal complex of a transition element is cobalt (II) acetylacetonate, cobalt(II)hexafluoroacetylacetonate hydrate, nickel(II)acetylacetonate, and di-n-butyldithiocarbamatenickel(II).

The most preferable metal complex of a transition element is cobalt(II)acetylacetonate and cobalt(II)hexafluoroacetylacetonate hydrate.

(5) Other Components

Monomer

The dye-containing curable composition of the invention suitably contains a monomer when the composition is constructed as a negative-type composition. The monomer is preferably a compound comprising ethylenic unsaturated groups containing at least one ethylene group capable of addition polymerization and a boiling point of 100° C. or more at normal pressures. Examples of the monomer-containing compounds include monofunctional acrylate and methacrylate such as polyethyleneglycol mono(meth)acrylate, polypropyleneglycol mono(meth)acrylate, phenoxyethyl (meth)acrylate; (meth)acrylate compounds prepared after an addition reaction of ethylene oxide or propylene oxide to polyfunctional alcohols such as polyethyleneglycol di(meth)acrylate, trimethylolethane tri(meth)acrylate, neopentylglycol di(meth)acrylate, pentaerythritol tri(meth)acrylate, pentaerythritol tetra(meth)acrylate, dipentaerythritol penta(meth)acrylate, dipentaerythritol hexa(meth)acrylate, hexanediol (meth)acrylate, trimethylolpropane tri(acryloyloxypropyl)ether, tri(acryloyloxyethyl) isocyanulate, glycerine and trimethylolethane; urethane acrylates described in JP-B Nos. 48-41708 and 50-6034, and JP-A No. 51-37193; polyester acrylates described in JP-A No. 48-64183 and JP-B No. 49-43191 and 52-30490; polyfunctional acrylate and methacrylate of epoxyacrylate as a reaction product of an epoxy resin and (meth)acrylic acid; and mixtures thereof. The compounds described in Nihon Secchaku Kyokai-shi Vol. 20, No. 7, pp. 300-308 as a photo-curable monomer and an oligomer are also included in the compounds of the invention.

The content of the monomer in the dye-containing curable composition is preferably 0.1 to 90% by mass, more preferably 1.0 to 80% by mass, and particularly 2.0 to 70% by mass relative to the solid content of the composition.

Cross-Linking Agent

The hardness of a layer may be enhanced by using an auxiliary cross-linking agent in the invention. The cross-linking agent will be described below.

The cross-linking agent available in the invention is not particularly restricted, so long as it is able to cure the layer with the cross-linking agent, and examples of the cross-linking agent include (a) epoxy resins, (b) melamine compounds, guanamine compounds, glycoluryl compounds or urea compounds substituted with at least one substituent selected from methylol group, alkoxymethyl group and acyloxymethyl group, and (c) phenol compounds, naphthol compounds or hydroxyanthrathene compounds substituted with at least one substituent selected from methylol group, alkoxymethyl group and acyloxymethyl group. A multifunctional epoxy resins are particularly preferable.

Any resins may be used as the epoxy resin in the (a) so long as the resin comprises epoxy groups and has a cross-linking property. Examples of the epoxy resin include glycidyl group-containing divalent low molecular weight compounds such as bisphenol A diglycidyl ether, ethyleneglycol diglycidyl ether, butanediol diglycidyl ether, hexanediol diglycidyl ether, dihydroxybiphenyl diglycidyl ether, diglycidyl phthalate and N,N-glycidylaniline; glycidyl group-containing trivalent low molecular weight compounds represented by trivalent trimethylolpropane triglycidyl ether, trimethylolphenol triglycidyl ether and tris P-PA triglycidyl ether; glycidyl group-containing tetravalent low molecular weight compounds represented by pentaerythritol tetraglycidyl ether and tetramethylol bisphenol A tetraglycidyl ether; glycidyl group-containing polyvalent low molecular weight compounds such as dipentaerythritol pentaglycidyl ether and dipentaerythritol hexaglycidyl ether; and glycidyl group-containing high molecular weight compounds represented by polyglycidyl(meth)acrylate and 1,2-epoxy-4-(2-oxylanyl)cyclohexane adduct of 2,2-bis(hydroxymethyl)-1-butanol.

The numbers of the methylol groups, alkoxymethyl groups and acyloxymethyl groups substituting the melamine compounds in (b) above are preferably 2 to 6, and the numbers of the groups above substituting the glycoluryl compounds, guanamine compounds and urea compounds, respectively, are preferably 2 to 4. More preferably, the numbers of the groups substituting the melamine compounds are 5 to 6, and the numbers of the groups substituting the glycoluryl compounds, guanamine compounds and urea compounds, respectively, are 3 to 4.

The melamine compounds, guanamine compounds, glycoluryl compounds and urea compounds are collectively named as the compounds according to (b) (methylol group-containing compounds, alkoxymethyl group-containing compounds or acyloxymethyl group-containing compounds) hereinafter.

The methylol group-containing compounds according to (b) can be obtained by heating the alkoxymethyl group-containing compounds according to (b) in an alcohol in the presence of an acid catalyst such as hydrochloric acid, sulfuric acid, nitric acid and methanesulfonic acid. The acyloxymethyl compounds according to (b) can be obtained by mixing acyl chloride with the methylol group-containing compounds according to (b) in the presence of a base catalyst.

Examples of the compounds according to (b) having the substituents above will be listed below.

Examples of the melamine compound include hexamethylol melamine, hexamethoxymethyl melamine and compounds having 1 to 5 methylol groups of hexamethylol melamine substituted with methoxymethyl groups, or a mixture thereof; and hexamethoxyethyl melamine, hexaacyloxymethyl melamine and compounds having 1 to 5 methylol groups of hexamethylol melamine substituted with acyloxymethyl groups, or a mixture thereof.

Examples of the guanamine compound include tetramethylol guanamine, tetramethoxymethyl guanamine and compounds having 1 to 3 methylol groups of tetramethylol guanamine substituted with methoxymethyl groups, or a mixture thereof; and tetramethoxyethyl guanamine, tetraacyloxymethyl guanamine and compounds having 1 to 3 methylol groups of tetramethylol guanamine substituted with acyloxymethyl groups, or a mixture thereof.

Examples of the glycoluryl compound include tetramethylol glycoluryl, tetramethoxymethyl glycoluryl and compounds having 1 to 3 methylol groups of tetramethylol glycoluryl substituted with methoxymethyl groups, or a mixture thereof; and compounds having 1 to 3 acyloxymethyl groups of tetramethylol glycoluryl substituted with acyloxymethyl groups, or a mixture thereof.

Examples of the urea compound include tetramethylol urea, tetramethoxymethyl urea and compounds having 1 to 3 methylol groups of tetramethylol urea substituted with methoxymethyl groups, or a mixture thereof; and tetramethoxyethyl urea.

The compounds according to (b) may be used alone, or as a combination thereof.

The compounds in the (c), that is, phenol compounds, naphthol compounds or hydroxyanthracene compounds substituted with at least one group selected from the methylol group, alkoxymethyl group and acyloxymethyl group can suppress inter-mixing of the curable resin composition with a overcoat photoresist by forming cross-links by heating as the case of the compounds in the (b), and the strength of the layer is enhanced. These compounds are collectively named as the compounds according to the (c) (methylol group-containing compounds, alkoxymethyl group-containing compounds or acyloxymethyl group-containing compounds).

At least two methylol groups, acyloxymethyl groups or alkoxymethyl groups should be contained per one molecule of the cross-linking agent in the (c). Compounds in which both the 2-position and 4-position of the phenol compound as a frame compound are substituted are preferable from the viewpoint of cross-linking ability by heating and preservation stability. Compounds in which both the ortho-position and para-position relative to the OH group of the naphthol compound or hydroxyanthracene compound as a frame compound are substituted are also preferable. The 3-position or 5-position of the phenol compound may be either substituted or unsubstituted.

Positions except the ortho-position relative to the OH group may be either substituted or unsubstituted in the naphthol compound.

The methylol group-containing compound according to the (c) may be obtained using a compound having a hydrogen atom at the ortho- or para-position (2- or 4-position) relative to the phenolic OH group as a starting material, and by allowing the material to react with formalin in the presence of a base catalyst such as sodium hydroxide, potassium hydroxide, ammonia or tetraalkylammonium hydroxide.

The alkoxymethyl group-containing compound according to the (c) may be obtained by heating the methylol group-containing compound according to the (c) in an alcohol in the presence of an acid catalyst such as hydrochloric acid, sulfuric acid, nitric acid or methanesulfonic acid.

The acyloxymethyl group-containing compound according to the (c) may be obtained by allowing the methylol group-containing compound according to the (c) to react with an acyl chloride in the presence of a base catalyst.

Examples of the frame compound of the cross-linking agent (c) include phenol, naphthol and hydroxyanthracene compounds in which the ortho- or para-position relative to the phenolic OH group is unsubstituted. Examples of the frame compound available include phenol, isomers of cresol, 2,3-xylenol, 2,5-xylenol, 3,4-xylenol, 3,5-xylenol, bisphenols such as bisphenol A, 4,4′-bishydroxybiphenyl, Tris P-PA (manufactured by Honshu Chemical Industry Co., Ltd.), naphthol, dihydroxynaphthalene and 2,7-dihydroxyanthracene.

Specific examples of the phenol compound or naphthol compound as the cross-linking agent (c) include trimethylolphenol, tri(methoxymethyl)phenol, and compounds having 1 to 2 methylol groups of trimethylol phenol substituted with methoxymethyl groups; trimethylol-3-cresol, tri(methoxymethyl)-3-cresol and compounds having 1 to 2 methylol groups of trimethylol-3-cresol substituted with methoxymethyl groups; dimethylcresol such as 2,6-dimethylol-4-cresol, tetramethylol bisphenol A, tetramethoxymethyl bisphenol A and compounds having 1 to 3 methylol groups of tetramethylol bisphenol A substituted with methoxymethyl groups; tetramethylol-4,4′-bishydroxybiphenyl, tetramethoxymethyl-4,4′-bishydroxybiphenyl, hexamethylol compounds of Tris P-PA, hexamethoxymethyl compounds of Tris P-PA, and compounds having 1 to 5 methylol groups of hexamethylol compound of Tris P-PA substituted with methoxymethyl groups; and bishydroxymethyl naphtalnediol.

Examples of the hydroxyanthracene compound include 1,6-dihydroxymethyl-2,7-dihydroxyanthracene.

Examples of the acyloxymethyl group-containing compound include methylol group-containing compounds in which a part or all the methylol groups are substituted with acyloxymethyl groups.

Preferable compounds among the compounds above include trimethylol phenol, bis hydroxymethyl-p-cresol, tetramethylol bisphenol A, and hexamethylol compounds of Tris P-PA (manufactured by Honshu Chemical Industry Co., Ltd.), or phenol compounds in which the methylol groups are substituted with the alkoxymethyl groups, and in which the methylol groups are substituted with both methylol groups and alkoxymethyl groups.

The compounds according to the (c) may be used alone, or as a combination thereof.

The cross-linking agent is not always contained in the curable composition according to the invention. The total content of the cross-linking agent, if any, according to (a) to (c) in the dye-containing curable composition is preferably 1 to 70% by mass, more preferably 5 to 50% by mass, and particularly 7 to 30% by mass, relative to the solid content (mass) of the curable composition, although the content differs depending on the materials used.

Organic Solvent

The dye-containing curable composition of the invention usually requires an organic solvent (simply referred to a solvent in the specification) for preparation. The solvent is not particularly restricted provided that it satisfies solubility of each component and coating ability of the dye-containing curable composition. The organic solvent is preferably selected considering solubility of the dye and alkali-soluble binder, coating ability and safety.

Examples of the preferable organic solvent include esters such as ethyl acetate, n-butyl acetate, isobutyl acetate, amyl formate, isoamyl acetate, butyl propionate, isopropyl butylate, ethyl butylate, butyl butylate, alkyl esters, methyl lactate, ethyl lactate, methyl oxylactate, ethyl oxylactate, butyl oxylactate, methyl methoxyacetate, ethyl methoxyacetate, butyl methoxyacetate, methyl ethoxyacetate, ethyl ethoxyacetate; 3-oxypropionic acid alkyl esters such as methyl 3-oxypropionate and ethyl 3-oxypropionate including methyl 3-methoxypropionate, ethyl 3-methoxypropionate, methyl 3-ethoxypropionate and ethyl 3-ethoxypropionate; 2-oxypropionic acid alkyl esters such as methyl 2-oxypropionate, ethyl 2-oxypropionate and propyl 2-oxypropionate including methyl 2-methoxypropyonate, ethyl 2-methoxypropionate, propyl 2-meoxypropionate, methyl 2-ethoxypropionate, ethyl 2-ethoxypropionate, methyl 2-oxy-2-methylpropionate, ethyl 2-oxy-2-methylpropionate, methyl 2-methoxy-2-methylpropionate, and ethyl 2-ethoxy-2-methylpropionate; methylpyruvate, ethyl pyruvate, propyl pyruvate, methyl acetoacetate, ethyl acetoacetate, methyl 2-oxobutanate and ethyl 2-oxobutanate; ethers such as diethyleneglycol dimethylether, tetrahydrofuran, ethyleneglycol monomethylether, ethyleneglycol monoethylether, methyl cellosolve acetate, ethyl cellosolve acetate, diethyleneglycol monomethylether, diethyleneglycol monoethylether, diethyleneglycol monobutylether, propyleneglycol methyl ether, propyleneglycol methylether acetate, propyleneglycol ethylether acetate, and propyleneglycol propylether acetate;

ketones such as methylethyl ketone, cyclohexanone, 2-heptanone and 3-heptanone; and aromatic hydrocarbons such as toluene and xylene.

Methyl 3-ethoxypropionate, ethyl 3-ethoxypropionate, ethyl cellosolve acetate, ethyl lactate, diethyleneglycol dimethylether, butyl acetate, methyl 3-methoxypropionate, 2-heptanone, cyclohexanone, ethylcarbitol acetate, butylcarbitol acetate, propyleneglycol methylether and propyleneglycol methylether acetate are more preferable among them.

Additives

Various additives such as fillers, polymer compounds other than those above, surfactants, adherence enhancing agents, antioxidants, ultraviolet absorbing agents and antiflocculants may be added, if necessary, to the dye-containing curable composition of the invention.

Specific examples of the additives include fillers such as glass and alumina; polymer compounds other than the binding resins such as polyvinyl alcohol, polyacrylic acid, polyethyleneglycol monoalkylether and polyfluoroalkyl acrylate; surfactants such as nonionic, cationic and anionic surfactants; adherence enhancing agents such as vinyl trimethoxy silane, vinyl triethoxy silane, vinyl tris(2-methoxyethoxy)silane, N-(2-aminoethyl)-3-aminopropylmethylmethoxy silane, N-(2-aminoethyl)-3-aminopropyltrimethoxy silane, 3-aminopropyltriethoxy silane, 3-glycidoxypropyl trimethoxy silane, 3-glycidoxypropyl methyldimethoxy silane, 2-(3,4-epoxycyclohexyl)ethyl trimethoxy silane, 3-chloropropylmethyl dimethoxy silane, 3-chloropropyl trimethoxy silane, 3-methacryloxypropyl trimethoxy silane, and 3-mercaptopropyl trimethoxy silane; antioxidants such as 2,2-thiobis(4-methyl-6-t-butylphanol) and 2,6-di-t-butylphenol; ultraviolet absorbing agents such as 2-(3-t-butyl-5-methyl-2-hydroxydiphenyl)-5-chlorobenzotriazole and alkoxybenzophenone; and antiflocculants such as sodium polyacrylate.

Organic carboxylic acids, preferably low molecular weight organic carboxylic acids with a molecular weight of 1000 or less may be added for enhancing alkali solubility of non-imaging parts to further improving development ability of the dye-containing curable composition of the invention.

Examples of the organic carboxylic acid include aliphatic monocarboxylic acids such as formic acid, acetic acid, propionic acid, butyric acid, valeric acid, pivalic acid, caproic acid, diethylacetic acid, enanthic acid and caprylic acid; aliphatic dicarboxylic acids such as oxalic acid, malonic acid, succinic acid, glutaric acid, adipic acid, pimelic acid, suberic acid, azelaic acid, sebacic acid, brassylic acid, methylmalonic acid, ethylmalonic acid, dimetylmalonic acid, methylsuccinic acid, tetramethylsuccinic acid and citraconic acid; aliphatic tricarboxylic acid such as tricarballylic acid, aconitic acid and camphoronic acid; aromatic monocarboxylic acid such as benzoic acid, toluic acid, cuminic acid, hemelitic acid and mesitylenic acid; aromatic polycarboxylic acid such as phthalic acid, isophthalic acid, terephthalic acid, trimellitic acid, trimesic acid, mellophanic acid and pyromellitic acid; and other carboxylic acid such as phenylacetic acid, hydroatropic acid, hydrocinnamic acid, mandelic acid, phenylsuccinic acid, atropic acid, cinnamic acid, methyl cinnamate, benzyl cinnamate, cinnamilydenic acid, cumalic acid and umbelic acid.

The dye-containing curable composition of the invention may be suitably used for color filters used for liquid crystal displays (LCD) and solid state image pick-up elements (for example CCD and CMOS), for forming colored pixels such as electroluminescence color filters, and for preparing printing inks, ink-jet inks and paints.

Color Filter and Preparation Process Thereof

The process of preparing the color filter of the invention will be described in detail hereinafter.

The color filter can be suitably prepared using the dye-containing curable composition of the invention in the process of preparing the color filter of the invention.

When the dye-containing curable composition of the invention is constructed as a negative-type composition, a radiation-sensitive composition layer is formed by applying the negative-type dye-containing curable composition on a substrate by a coating process such as rotation coating, drip coating and roll coating. Then, the layer is exposed through a given mask pattern followed by developing with a developer to consequently form a negative-type colored pattern (image forming step). A curing step may be applied, if necessary, for curing the colored pattern formed by either heating or exposure at least.

When the dye-containing curable composition of the invention is constructed as a positive-type composition, a radiation-sensitive composition layer is formed by applying the positive-type dye-containing curable composition on a substrate by a coating process such as rotation coating, flow casting coating and roll coating. Then, the layer is exposed through a given mask pattern followed by developing with a developer. Consequently, the colored pattern formed is cured by heating (post-baking) after forming a positive-type colored pattern (image forming step).

The negative-type color filter comprising desired hues may be prepared by repeating the plural times of the image forming steps (and curing step, if necessary) corresponding to the number of the hues. The positive-type color filter comprising desired hues may be prepared by repeating the plural times of the image forming steps and post-baking steps corresponding to the number of the hues.

Particularly preferable light or radiation used for the purpose above is an ultraviolet light such as g-ray, h-ray and i-ray.

Examples of the substrate include a soda glass, Pyrex (R) glass and quartz glass, which are used for a liquid crystal displays those on which a transparent conductive film is adhered, and the substrate of photoelectric conversion elements used for the imaging element such as, for example, a silicone substrate and complementary metal oxide film semiconductor (CMOS). Black stripes for isolating each pixel may be formed on these substrates.

An undercoat layer may be provided on the substrate for improving adhesive property to the upper layers, for preventing diffusion of substances, and for planarizing the surface of the substrate.

Any developers may be used so long as they comprise a composition that is able to dissolve non-cured portions of the dye-containing curable composition of the invention while the cured portions are left undissolved. Specifically, a combination of various organic solvents and an aqueous alkali solution may be used. The organic solvents used for preparing the dye-containing curable composition of the invention may be also used for the developer.

Examples the alkali used for the aqueous alkali solution include alkaline compounds such as sodium hydroxide, potassium hydroxide, sodium carbonate, sodium silicate, sodium metasilicate, aqueous ammonia, ethylamine, diethylamine, diethanolamine, tetramethylammonium hydroxide, tetraethylammonium hydroxide, choline, pyrrole, piperidine and 1,8-diazabicyclo-[5.4.0]-7-undecene. It is suitable to dissolve the aqueous alkaline solution in a concentration of 0.001 to 10% by mass, preferably 0.01 to 1% by mass. The colored pattern is usually washed with water after it is developed with such aqueous alkaline solution.

The color filter of the invention can be used for the liquid crystal display (LCD) and solid state image pick-up element (for example CCD and CMOS). The color filter is suitable for a high resolution CCD element and CMOS having 1,000,000 pixels or more. The color filter of the invention may be used by disposing between the light-receiving part of the pixels constituting the CCD and micro-lenses for converging the light.

### EXAMPLES

While the present invention is described in detail with reference to examples of the invention, the invention is not restricted to the examples as set forth below within the range not departing the spirit of the invention. “Parts” used in the examples denote “parts by mass”, unless otherwise stated.

### Example 1

(1) Preparation of resist solution

| | | |
|---|---|---|
| ethyl lactate | 75 | parts |
| binder | 7.0 | parts |
| [benzyl methacrylate/methacrylic acid copolymer (7/3 in | | |
| molar ratio)] | | |
| polymerization inhibitor (p-methoxyphenol) | 0.005 | parts |
| fluorine based surfactant | 0.4 | parts |
| (trade name: F-475, manufactured by Dainippon Ink and | | |
| Chemicals, Inc.) | | |
| dipentaerythritol hexaacrylate | 9.8 | parts |
| (photopolymerizable compound) | | |
| photopolymerization initiator | 1.2 | parts |
| (trade name: TAZ-107, manufactured by Midori Kagaku | | |
| Co., Ltd.) | | |

These compounds were mixed and dissolved to prepare a resist solution.

(2) Preparation of Glass Substrate Provided with Subbing Layer

A glass substrate (trade name: CORNING™ 1737) was washed with an aqueous 1% NaOH solution by applying an ultrasonic wave, and was washed with water followed by baking for dehydration (200° C./30 minutes). Then, the resist solution obtained in step (1) was applied with a spin coater on the cleaned glass substrate at a thickness of 2 μm, followed by drying the layer at 220° C. for 1 hour to form a cured film (undercoat layer).

(3) Preparation of negative-type dye-containing curable
composition A-1

| | | |
|---|---|---|
| ethyl lactate | 75 | parts |
| binder | 7.0 | parts |
| [allyl methacrylate/methacrylic acid copolymer (5/5 in | | |
| molar ratio)] | | |
| yellow dye (Valifast Yellow 1101) | 6.0 | parts |
| polymerization inhibitor (p-methoxyphenol) | 0.005 | parts |
| fluorine based surfactant | 0.4 | parts |
| [trade name: F-475 manufactured by Dainippon Ink and | | |
| Chemicals, Inc.] | | |
| dipentaerythritol hexaacrylate (monomer) | 9.8 | parts |
| photopolymerization initiator | 1.2 | parts |
| [trade name: CGI-124 manufactured by Ciba-Geigy Corp.] | | |
| nickel (II) acetylacetonate | 0.6 | parts |

These compounds were mixed and dissolved to prepare negative-type dye-containing curable composition A-1.

(4) Exposure and Development of Dye-Containing Curable Composition (Image Formation)

Negative-type dye-containing curable composition A-1 obtained in step (3) was applied on the undercoat layer of the glass substrate with the undercoat layer obtained in (2) at a thickness of 1.3 μm using a spin coater, and the layer was pre-baked at 120° C. for 120 seconds.

A light with a wavelength of 365 nm was irradiated on the entire surface of the coating layer with a luminous exposure of 500 mJ/cm² using an exposure device. After irradiation, the layer was developed at 23° C. for 60 seconds using a developer (trade name: CD-2000, manufactured by Fuji Film Arch Co., Ltd.; 50% aqueous solution). Subsequently, the film was rinsed with running water for 20 seconds. After spray drying, the layer was heated at 200° C. for 300 seconds (post-baking) to obtain a colored (yellow) filter film.

(5) Evaluation

The colored filter film obtained as described above was evaluated with respect to light fastness and retained layer rate after development.

A light from a xenon lamp was irradiated on the glass substrate having the undercoat layer, on which the colored filter film was formed, at a luminous energy of 200,000 lux for 10 hours (corresponds to a total luminous energy of 2,000,000 lux·h). Then, changes of the chroaticity in the patterned image, that is ΔEab, was measured to evaluate light fastness of the film based on the measured values. The smaller ΔEab value shows the better light fastness.

The retained layer rate after development shows the ratio (%) of the absorbance of the filter film after the development to the absorbance before the development. Visible light absorption spectra of the filter film before and after the development were measured using a color-meter (trade name: MCPD-1000, manufactured by Otsuka Electronics Co., Ltd.), and the measured values were evaluated using the absorbance ratio at the maximum absorption wavelength λmax of the dye as a reference. The larger value shows better pattern shape.

### Examples 2 to 13 and Comparative Examples 1 to 3

Negative-type dye-containing curable compositions A-2 to A-13 and A-14 to A-16 were prepared by the same process as in Example 1, except that the yellow dye (Valifast Yellow 1101) and metal complex of a transition element (nickel (II) acetylacetonate) used in “(3) preparation of negative-type dye-containing curable composition A-1” were changed to the dyes and metal complex of a transition elements, respectively, in Table 1 below. Then, the colored filter films were formed and evaluated as in Example 1. The results of evaluation are shown in Table 1.

TABLE 1

| | | | | | Retained layer |
|---|---|---|---|---|---|
| | Negative-type | | | Light fastness | rate after |
| | composition(*1) | dye | Metal complex of a transition element | (Δ Eab) | development(%) |
| Example 1 | A-1 | Valifast Yellow 1101 | Nickel(II) acetylacetonate | 0.8 | 98 |
| Example 2 | A-2 | Valifast Yellow 1101 | Cobalt(II) acetylacetonate | 0.7 | 99 |
| Example 3 | A-3 | Valifast Yellow 1101 | Dichlorotetrakis(triphenylphosphine) | 2.7 | 92 |
| | | | ruthenium(II) | | |
| Example 4 | A-4 | Valifast Yellow 1101 | Tris(triphenylphosphine)copper(I) | 1.7 | 95 |
| | | | chloride | | |
| Example 5 | A-5 | C.I. Acid Red 249 | Bis(cis-1,2-diaminocyclohexane) | 1.0 | 97 |
| | | | nickel(II) chloride | | |
| Example 6 | A-6 | C.I. Acid Red 249 | Di-n-butyldithiocarbamate copper(II) | 0.9 | 97 |
| Example 7 | A-7 | C.I. Acid Red 249 | Dichlorobis(triethylphosphine) | 2.2 | 93 |
| | | | palladium(II) | | |
| Example 8 | A-8 | C.I. Acid Blue 80 | Tetrakispyridine iron(II) bromide | 0.9 | 98 |
| Example 9 | A-9 | C.I. Acid Blue 80 | Tris(2,2′-bipyridyl)rhutenium(II) | 2.6 | 91 |
| | | | chloride hexahydrate | | |
| Example 10 | A-10 | C.I. Acid Blue 80 | Manganese chloride tetrahydrate | 0.8 | 98 |
| Example 11 | A-11 | The mixture of | Cobalt(II) acetylacetonate | 1.0 | 96 |
| | | Acid Red 97(37%), | | | |
| | | Solvent Orange 26(23%) | | | |
| | | and | | | |
| | | Solvent Yellow 14(40%) | | | |
| Example 12 | A-12 | The mixture of | Di-n-butyldithiocarbamate nickel(II) | 1.1 | 96 |
| | | Acid Yellow 76(57%) | | | |
| | | and | | | |
| | | Valifast Blue 2620(43%) | | | |
| Example 13 | A-13 | Solvent Blue 37 | Cobalt(II) hexafluoroacetylacetonate | 1.0 | 97 |
| | | | hydrate | | |
| Comparative | A-13 | Valifast Yellow 1101 | — | 10.0 | 80 |
| example 1 | | | | | |
| Comparative | A-14 | C.I. Acid Red 249 | — | 8.5 | 83 |
| example 2 | | | | | |
| Comparative | A-15 | C.I. Acid Blue 80 | — | 8.6 | 81 |
| example 3 | | | | | |

(*1)Negative-type dye-containing curable composition

As shown in Table 1, all the filter films prepared by using the negative-type dye-containing compositions A-1 to A-13 of the invention showed high light fastness and had good retained layer rate after development. On the other hand, the filter films prepared by using the negative-type dye-containing compositions A-14 to A-16 as the comparative examples were poor in light fastness and retained layer rate after development.

### Example 14

The negative-type dye-containing curable composition A-1 prepared in step (3) in Example 1 was changed to the positive-type dye-containing curable composition B-1 prepared as described in step (6) below. The colored filter film was formed by the same process as in example 1 except for using the curable composition B-1 and irradiating on the entire surface of the coating layer with a light having a wavelength of 193 nm. The film was evaluated as in Example 1. The result is shown in Table 2.

(6) Preparation of positive-type dye-containing curable
composition B-1

| | | |
|---|---|---|
| ethyl lactate | 7.5 | parts |
| binder P-1 described below | 14.0 | parts |
| yellow dye (C.I. acid yellow 29) | 6.0 | parts |
| photo-acid-generating agent PAG-1 described below | 4.0 | parts |
| fluorine based surfactant | 0.4 | parts |
| (trade name: F-475, manufactured by Dainippon Ink and | | |
| Chemicals, Inc.) | | |
| diisopropyl dithiophosphate nickel (II) | 0.6 | parts |

These compounds were mixed and dissolved to prepare positive-type dye-containing curable composition B-1.

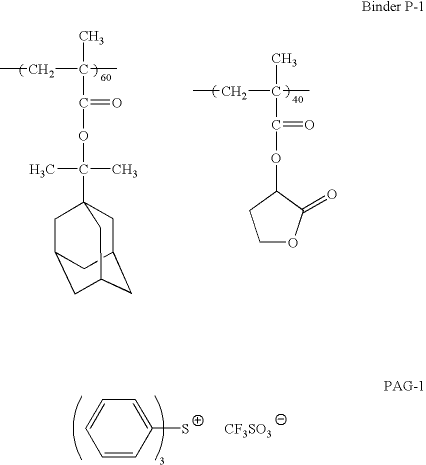

### Examples 15 to 22 and Comparative Examples 4 to 6

Positive-type dye-containing curable compositions B-2 to B-9 and B-10 to B-12 were prepared by the same process as in Example 14, except that the yellow dye (C.I. acid yellow 29) and metal complex of a transition element (diisopropyl dithiophosphate nickel(II)) used in “(6) preparation of positive-type dye-containing curable composition B-1”

were changed to the dyes and metal complex of a transition elements, respectively, in Table 2 below. Then, the colored filter films were formed and evaluated as in Example 14. The results of evaluation are shown in Table 2 below.

TABLE 2

| | | | | | Retained layer |
|---|---|---|---|---|---|
| | Positive-type | | | Light fastness | rate after |
| | composition(*1) | dye | Metal complex of a transition element | (Δ Eab) | development(%) |
| Example 14 | B-1 | C.I. Acid Yellow 29 | Diisopropyl dithiophosphate nickel(II) | 0.9 | 97 |
| Example 15 | B-2 | C.I. Acid Yellow 29 | Nitrosyl tris(triphenylphosphine) | 2.4 | 92 |
| | | | rhodium(I) | | |
| Example 16 | B-3 | C.I. Acid Red 143 | Cobalt chloride hexahydrate | 0.8 | 98 |
| Example 17 | B-4 | C.I. Acid Red 143 | Diethyl dithiophosphate palladium | 2.8 | 93 |
| Example 18 | B-5 | C.I. Acid Blue 23 | Tetrekis-γ-picoline iron(II) bromide | 1.0 | 96 |
| Example 19 | B-6 | C.I. Acid Blue 23 | Bis(acetonitrile)dichloropalladium(II) | 2.6 | 93 |
| Example 20 | B-7 | The mixture of | Di-n-butyldithiocarbamate nickel(II) | 1.0 | 96 |
| | | Acid Red 97(37%), | | | |
| | | Solvent Orange 26(23%) | | | |
| | | and | | | |
| | | Solvent Yellow 14(40%) | | | |
| Example 21 | B-8 | The mixture of | Cobalt(II) hexafluoroacetylacetonate | 1.2 | 95 |
| | | Acid Yellow 76(57%) | hydrate | | |
| | | and | | | |
| | | Valifast Blue 2620(43%) | | | |
| Example 22 | B-9 | Solvent Blue 37 | Nickel(II) bis(2,2,6,6-tetramethy-3,5- | 1.3 | 95 |
| | | | heptanedionato) | | |
| Comparative | B-10 | C.I. Acid Yellow 29 | — | 7.0 | 83 |
| example 4 | | | | | |
| Comparative | B-11 | C.I. Acid Red 143 | — | 8.4 | 84 |
| example 5 | | | | | |
| Comparative | B-12 | C.I. Acid Blue 23 | — | 9.5 | 81 |
| example 6 | | | | | |

(*1)Positive-type dye-containing curable composition

As shown in Table 2, all the filter films prepared by using the positive-type dye-containing curable compositions B-1 to B-9 of the invention showed high light fastness and had good retained layer rate after development. On the other hand, the filter films prepared by using the curable compositions B-10 to B-12 in the comparative examples were poor in both light fastness and retained layer rate after development.

### Example 23

The negative-type dye-containing curable composition A-1 prepared in step (3) in Example 1 was changed to the positive-type dye-containing curable composition C-1 prepared as described in step (7) below. The colored filter film was formed by the same process as in example 1 except for using the curable composition C-1. The film was evaluated as in Example 1. The result is shown in Table 3.

(7) Preparation of positive-type dye-containing curable
composition C-1

| | | |
|---|---|---|
| ethyl lactate | 75 | parts |
| binder | 14 | parts |
| [benzyl methacrylate/methacrylic acid/2-hydroxyethyl | | |
| methacrylate copolymer (6/3/1 in molar ratio)] | | |
| yellow dye (C.I. acid yellow 65) | 6.0 | parts |
| ester compound of 2,3,4-trihydroxybenzophenone and o- | 4.0 | parts |
| naphthoquinone-diazide-5-sulfolylchloride (esterification | | |
| rate 80 mol %; quinonediazo compound) | | |
| fluorine bases surfactant | 0.4 | parts |
| (trade name: F-475, manufactured by Dainippon Ink and | | |
| Chemicals, Inc.) | | |
| bis(salicylaldehyde) cobalt (II) hydrate | 0.6 | parts |

These compounds were mixed and dissolved to obtain the positive-type dye-containing curable composition C-1.

### Examples 24 to 35 and Comparative Examples 7 to 9

Positive-type dye-containing curable compositions C-2 to C-13 and C-14 to C-16 were prepared by the same process as in Example 23, except that the yellow dye (C.I. acid yellow 65) and metal complex of a transition element (bis(salicylaldehyde) cobalt(II) dihydrate) used in “(7) preparation of positive-type dye-containing curable composition C-1” were changed to the dyes and metal complex of a transition elements, respectively, in Table 3 below. Then, the colored filter films were formed and evaluated as in Example 23. The results of evaluation are shown in Table 3 below.

TABLE 3

| | | | | | Retained layer |
|---|---|---|---|---|---|
| | Positive-type | | | Light fastness | rate after |
| | composition(*1) | dye | Metal complex of a transition element | (Δ Eab) | development(%) |
| Example 23 | C-1 | C.I. Acid Yellow 65 | Bis(salicylaldehyde)cobalt(II) dihydrate | 0.8 | 99 |
| Example 24 | C-2 | C.I. Acid Yellow 65 | Bis(tetraethylammonium)tetrabromo | 1.0 | 97 |
| | | | manganese(II) | | |
| Example 25 | C-3 | C.I. Acid Yellow 65 | Tris(ethylenediamine)rhodium(III) | 2.6 | 90 |
| | | | chloride trihydrtae | | |
| Example 26 | C-4 | C.I. Acid Yellow 65 | Tetra(diethylamino)titanium | 1.3 | 95 |
| Example 27 | C-5 | C.I. Acid Red 57 | Di-n-butyl dithiocarbamate cobalt(II) | 0.8 | 99 |
| Example 28 | C-6 | C.I. Acid Red 57 | Cobalt(II) hexafluoroacetylacetonate | 0.8 | 99 |
| | | | hydrate | | |
| Example 29 | C-7 | C.I. Acid Red 57 | Trichlorobis(2-phenylpyridine) | 2.9 | 92 |
| | | | rhodium(III) dimer | | |
| Example 30 | C-8 | C.I. Acid Blue 92 | Copper bis(2,2,6,6-tetramethyl-3,5- | 0.9 | 97 |
| | | | heptanedionato) | | |
| Example 31 | C-9 | C.I. Acid Blue 92 | Chromium(III) acetylacetonate | 2.6 | 93 |
| Example 32 | C-10 | C.I. Acid Blue 92 | N-butylamino[2,2′-thiobis(4-t- | 0.9 | 97 |
| | | | octyl)phanolate]cobalt(II) | | |
| Example 33 | C-11 | The mixture of | Di-n-butyldithiocarbamate cobalt(II) | 1.0 | 97 |
| | | Acid Red 97(37%), | | | |
| | | Solvent Orange 26(23%) | | | |
| | | and | | | |
| | | Solvent Yellow 14(40%) | | | |
| Example 34 | C-12 | The mixture of | Cobalt(II) hexafluoroacetylacetonate | 0.9 | 95 |
| | | Acid Yellow 76(57%) | hydrate | | |
| | | and | | | |
| | | Valifast Blue 2620(43%) | | | |
| Example 35 | C-13 | Solvent Blue 37 | Cobalt(II) acetylacetonate | 0.9 | 96 |
| Comparative | C-14 | C.I. Acid Yellow 65 | — | 7.8 | 82 |
| example 7 | | | | | |
| Comparative | C-15 | C.I. Acid Red 57 | — | 9.7 | 80 |
| example 8 | | | | | |
| Comparative | C-16 | C.I. Acid Blue 92 | — | 9.3 | 86 |
| example 9 | | | | | |

(*)1Positive-type dye-containing curable composition

As shown in Table 3, all the filter films prepared by using the positive-type dye-containing curable compositions C-1 to C-13 of the invention showed high light fastness and had good retained layer rate after development. On the other hand, the filter films prepared by using the curable compositions C-14 to C-16 in the comparative examples were poor in both light fastness and retained layer rate after development.

The invention provides a dye-containing curable composition having high light fastness after alkali development as well as good retained layer rate after development.

The invention also provide a color filter constituted using the dye-containing curable composition, which is excellent in hues and resolution and has high light fastness.

The invention further provides a process of preparing the color filter that is excellent in hues and resolution as a result of suppressing retained layer ratio after alkali development from decreasing, and has high light fastness.

1-9. (canceled)

10. A color filter prepared by using a dye-containing curable composition containing at least an alkali soluble binder, an organic-solvent-soluble dye, a radiation-sensitive compound and a metal complex of a transition element in which the maximum value of a molar absorption coefficient ε in a visible light range is smaller than that of the organic-solvent-soluble.

11. The color filter according to claim 10, wherein the radiation-sensitive compound is at least one kind selected from a photopolymerization initiator and a photo-acid-generating agent and the dye-containing curable composition is structured as a negative-type dye-containing curable composition.

12. The color filter according to claim 11, wherein the dye-containing curable composition comprises a monomer.

13. The color filter according to claim 10, wherein the radiation-sensitive compound is a photo-acid-generating agent, and the dye-containing curable composition is structured as a positive-type dye-containing curable composition.

14. The color filter according to claim 10, wherein the radiation-sensitive compound is an o-quinone-diazide compound, and the dye-containing curable composition is structured as a positive-type dye-containing curable composition.

15. The color filter according to claim 10, wherein the dye-containing curable composition comprises a cross-linking agent.

16. A process of preparing a color filter comprising the steps of: applying a dye-containing curable composition containing at least an alkali soluble binder, an organic-solvent-soluble dye, a radiation-sensitive compound and a metal complex of a transition element in which the maximum value of a molar absorption coefficient ε in a visible light range is smaller than that of the organic-solvent-soluble on a substrate; exposing the dye-containing curable composition through a mask; and forming a pattern image by development.

17. The process of preparing a color filter according to claim 16, wherein the radiation-sensitive compound is at least one kind selected from a photopolymerization initiator and a photo-acid-generating agent, and the dye-containing curable composition is structured as a negative-type dye-containing curable composition.

18. The process of preparing a color filter according to claim 17, wherein the dye-containing curable composition comprises a monomer.

19. The process of preparing a color filter according to claim 16, wherein the radiation-sensitive compound is a photo-acid-generating agent, and the dye-containing curable composition is structured as a positive-type dye-containing curable composition.

20. The process of preparing a color filter according to claim 16, wherein the radiation-sensitive compound is an o-quinone-diazide compound, and the dye-containing curable composition is structured as a positive-type dye-containing curable composition.

21. The process of preparing a color filter according to claim 16, wherein the dye-containing curable composition comprises a cross-linking agent.
